(19) United States
(12) Patent Application Publication
(10) Pub. No.: US 2026/0107537 A1
(43) Pub. Date: Apr. 16, 2026

(54) EPITAXIAL WAFER, ß-Ga2O3-BASED DEVICE, AND METHOD FOR FABRICATING ß-Ga2O3-BASED DEVICE

(71) Applicant: Panasonic Intellectual Property Management Co., Ltd., Osaka (JP)

(72) Inventors: Hidetaka SUGAYA, Shiga (JP); Nobuya NAKADE, Osaka (JP); Shizuo FUJITA, Kyoto (JP); Hikaru IKEDA, Kyoto (JP); Katsutoshi FUKUDA, Kyoto (JP)

(73) Assignee: Panasonic Intellectual Property Management Co., Ltd., Osaka (JP)

(21) Appl. No.: 19/420,339

(22) Filed: Dec. 15, 2025

Related U.S. Application Data
(63) Continuation of application No. PCT/JP2024/021165, filed on Jun. 11, 2024.

(30) Foreign Application Priority Data
Jun. 19, 2023 (JP) 2023-100237

(51) Int. Cl. H10D 62/80; H10D 30/87

(52) U.S. Cl. CPC H10D 62/875; H10D 30/87

(57) ABSTRACT

An epitaxial wafer 1 includes a Ga₂O₃-based substrate, a metal layer, and a β-Ga₂O₃ layer. The Ga₂O₃-based substrate has a first principal surface and a second principal surface opposite from the first principal surface. The metal layer is formed on the first principal surface of the Ga₂O₃-based substrate. The metal layer has a plurality of openings. The β-Ga₂O₃ layer covers the first principal surface of the Ga₂O₃-based substrate and the metal layer. The metal layer is made of a material such as a noble metal or a refractory metal. The thickness of the β-Ga₂O₃ layer is smaller than the thickness of the Ga₂O₃-based substrate.

### CROSS-REFERENCE TO RELATED APPLICATIONS

The present application is a Bypass Continuation of International Application No. PCT/JP2024/021165 filed on Jun. 11, 2024, which is based upon, and claims the benefit of priority to, Japanese Patent Application No. 2023-100237, filed on Jun. 19, 2023. The entire contents of both applications are hereby incorporated by reference.

### TECHNICAL FIELD

The present disclosure generally relates to an epitaxial wafer, a β-Ga₂O₃-based device, and a method for fabricating the β-Ga₂O₃-based device. More particularly, the present disclosure relates to an epitaxial wafer including a β-Ga₂O₃ layer, a β-Ga₂O₃-based device, and a method for fabricating the β-Ga₂O₃-based device.

### BACKGROUND ART

JP 2021-136331 A discloses, as a power device, a field effect transistor (β-Ga₂O₃-based device) including a substrate made of Ga₂O₃, for example, and a Ga₂O₃-based semiconductor layer which is an epitaxial layer formed by an epitaxial growing process using the substrate as a base member. The crystal structure of Ga₂O₃ single crystals that form the Ga₂O₃-based semiconductor layer is the β-type which belongs to the monoclinic crystal system.

JP 2021-136331 A also teaches that the substrate does not have to be made up of Ga₂O₃-based single crystals but may also be made of sapphire, for example.

The β-Ga₂O₃-based device may have its characteristics adversely affected by the effect of the substrate that forms the base member of the Ga₂O₃-based semiconductor layer.

### SUMMARY

The present disclosure provides an epitaxial wafer, a β-Ga₂O₃-based device, and a method for fabricating the β-Ga₂O₃-based device, all of which may contribute to improving the characteristics of the β-Ga₂O₃-based device.

An epitaxial wafer according to an aspect of the present disclosure includes a Ga₂O₃-based substrate, a metal layer, and a β-Ga₂O₃ layer. The Ga₂O₃-based substrate has a first principal surface and a second principal surface opposite from the first principal surface. The metal layer is formed on the first principal surface of the Ga₂O₃-based substrate. The metal layer has a plurality of openings. The β-Ga₂O₃ layer covers the first principal surface of the Ga₂O₃-based substrate and the metal layer. The metal layer is made of a material such as a noble metal or a refractory metal. The thickness of the β-Ga₂O₃ layer is smaller than the thickness of the Ga₂O₃-based substrate.

A β-Ga₂O₃-based device according to another aspect of the present disclosure includes a Ga₂O₃-based substrate, a metal layer, a β-Ga₂O₃ layer, and a semiconductor element. The Ga₂O₃-based substrate has a first principal surface and a second principal surface opposite from the first principal surface. The metal layer is formed selectively on the first principal surface of the Ga₂O₃-based substrate. The β-Ga₂O₃ layer covers the first principal surface of the Ga₂O₃-based substrate and the metal layer. The semiconductor element includes at least a part of the β-Ga₂O₃ layer. The metal layer is made of a material such as a noble metal or a refractory metal. The thickness of the β-Ga₂O₃ layer is smaller than the thickness of the Ga₂O₃-based substrate.

A method for fabricating a β-Ga₂O₃-based device according to still another aspect of the present disclosure includes a substrate providing process step, a metal layer forming process step, and an epitaxial growing process step. The substrate providing process step includes providing a Ga₂O₃-based substrate having a first principal surface and a second principal surface opposite from the first principal surface. The metal layer forming process step includes forming a metal layer having a plurality of openings on the first principal surface of the Ga₂O₃-based substrate. The epitaxial growing process step includes forming a β-Ga₂O₃ layer that covers the first principal surface of the Ga₂O₃-based substrate and the metal layer by epitaxial lateral overgrowth using a mist CVD method. The metal layer is made of a material such as a noble metal or a refractory metal. The thickness of the β-Ga₂O₃ layer is smaller than the thickness of the Ga₂O₃-based substrate.

### BRIEF DESCRIPTION OF DRAWINGS

The figures depict one or more implementations in accordance with the present teaching, by way of example only, not by way of limitations. In the figures, like reference numerals refer to the same or similar elements.

FIG. 1 is a cross-sectional view illustrating a main part of an epitaxial wafer according to a first embodiment;

FIG. 2 is a plan view illustrating the main part of the epitaxial wafer;

FIG. 3 is a partially cutaway perspective view of the epitaxial wafer, of which a β-Ga₂O₃ layer is not shown there;

FIG. 4A-4E are cross-sectional views illustrating main process steps of a method for fabricating the epitaxial wafer;

FIG. 5 illustrates the epitaxial wafer;

FIG. 6 is a cross-sectional view of a β-Ga₂O₃-based device according to the first embodiment;

FIG. 7 is a plan view of the β-Ga₂O₃-based device;

FIG. 8 is a cross-sectional view illustrating a main part of an epitaxial wafer according to a variation of the first embodiment;

FIG. 9 is a cross-sectional view of a β-Ga₂O₃-based device according to a second embodiment;

FIG. 10 is a plan view of the β-Ga₂O₃-based device;

FIG. 11 is a cross-sectional view illustrating a main process step of a method for fabricating the β-Ga₂O₃-based device;

FIG. 12 is a plan view illustrating a main process step of the method for fabricating the β-Ga₂O₃-based device;

FIG. 13 is a cross-sectional view of a β-Ga₂O₃-based device according to a third embodiment;

FIG. 14 is a plan view of the β-Ga₂O₃-based device;

FIG. 15 is a cross-sectional view of a β-Ga₂O₃-based device according to a fourth embodiment;

FIG. 16 is a plan view of the β-Ga₂O₃-based device;

FIG. 17 is a cross-sectional view of a β-Ga₂O₃-based device according to a fifth embodiment;

FIG. 18 is a cross-sectional view of a β-Ga₂O₃-based device according to a sixth embodiment;

FIG. 19 is a cross-sectional view of a β-Ga₂O₃-based device according to a seventh embodiment;

FIG. 20 is a plan view of the β-Ga₂O₃-based device;

FIG. 21 is a cross-sectional view of a β-Ga₂O₃-based device according to an eighth embodiment;

FIG. 22 is a plan view illustrating a metal layer of the β-Ga₂O₃-based device;

FIG. 23A-23C are cross-sectional views illustrating main process steps of a method for fabricating the β-Ga₂O₃-based device; and

FIG. 24 is a plan view illustrating a metal layer of a β-Ga₂O₃-based device according to a variation of the eighth embodiment.

### DETAILED DESCRIPTION

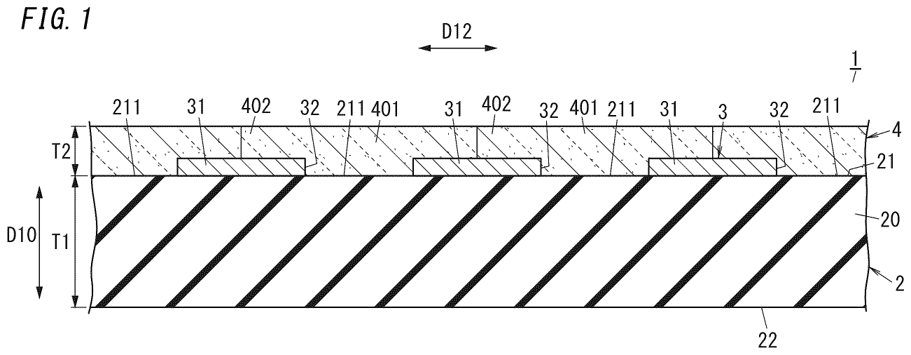

FIG. 1-24 to be referred to in the following description of first to eighth embodiments and their variations are all schematic representations. Thus, the ratio of the dimensions (including thicknesses) of respective constituent elements illustrated on the drawings does not always reflect their actual dimensional ratio.

### First Embodiment

### (1) Epitaxial Wafer and Method for Fabricating the Same

An epitaxial wafer 1 according to a first embodiment and a method for fabricating the epitaxial wafer 1 will now be described with reference to FIG. 1-5.

### (1.1) Epitaxial Wafer

An epitaxial wafer 1 according to the first embodiment includes a Ga₂O₃-based substrate 2, a metal layer 3, and a β-Ga₂O₃ layer 4 as shown in FIG. 1. The Ga₂O₃-based substrate 2 has a first principal surface 21 and a second principal surface 22 opposite from the first principal surface 21. The metal layer 3 is formed on the first principal surface 21 of the Ga₂O₃-based substrate 2. The metal layer 3 has a plurality of openings 32. Thus, the metal layer 3 is formed selectively on the first principal surface 21 of the Ga₂O₃-based substrate 2. The β-Ga₂O₃ layer 4 covers the first principal surface 21 of the Ga₂O₃-based substrate 2 and the metal layer 3. The epitaxial wafer 1 is a β-Ga₂O₃ epitaxial wafer. The β-Ga₂O₃ epitaxial wafer is a wafer formed by epitaxially growing the β-Ga₂O₃ layer 4 on the Ga₂O₃-based substrate 2 which is a wafer including β-Ga₂O₃ crystals.

In the epitaxial wafer 1 according to the first embodiment, the Ga₂O₃-based substrate 2 is a β-Ga₂O₃ substrate 20. The β-Ga₂O₃ substrate 20 is made up of β-Ga₂O₃ single crystals. The crystal structure of the β-Ga₂O₃ single crystals is a monoclinic crystal system. The first principal surface 21 of the Ga₂O₃-based substrate 2 may be, but does not have to be, a (010) plane or a (001) plane of β-Ga₂O₃ single crystals, for example. As used herein, each of the (010) and (001) planes is a crystallographic plane expressed by three Miller indices placed in parentheses. Optionally, the first principal surface 21 of the Ga₂O₃-based substrate 2 may also be a crystallographic plane that forms an off-axis angle with respect to the (010) or (001) plane of β-Ga₂O₃ single crystals. Also, in the epitaxial wafer 1 according to the first embodiment, the β-Ga₂O₃ substrate 20 is a semi-insulating β-Ga₂O₃ substrate. The semi-insulating β-Ga₂O₃ substrate is a β-Ga₂O₃ substrate having a resistivity equal to or higher than 1×10⁸ Ωcm and equal to or lower than 1×10¹² Ωcm.

The Ga₂O₃-based substrate 2 has a substantially circular shape when viewed in plan in a thickness direction D10 defined with respect to the Ga₂O₃-based substrate 2. The Ga₂O₃-based substrate 2 may have a diameter equal to or greater than 50 mm and equal to or less than 150 mm, for example. The Ga₂O₃-based substrate 2 may have a thickness T1 equal to or greater than 400 μm and equal to or less than 800 μm, for example.

The metal layer 3 may be made of a material such as a noble metal or a refractory metal. If a noble metal is used as a material for the metal layer 3, the noble metal may be Pt or Au, for example, but may also be any noble metal other than Pt and Au. If a refractory metal is used as a material for the metal layer 3, the refractory metal may be Ta or W, for example, but may also be any refractory metal other than Ta and W.

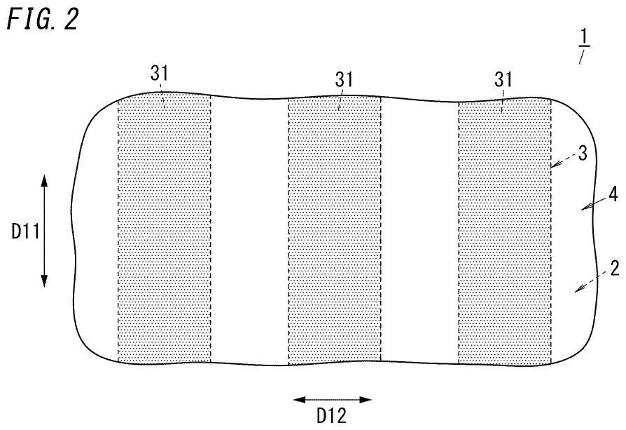

The metal layer 3 includes a plurality of metallic parts 31. Each of the plurality of metallic parts 31 has a linear (elongate) shape. In the following description, the longitudinal axis of each of the plurality of metallic parts 31 is herein defined to be a first direction D11 (refer to FIG. 2) and a direction perpendicular to both the thickness direction D10 defined with respect to the Ga₂O₃-based substrate 2 and the first direction D11 is herein defined to be a second direction D12. As used herein, the “elongate shape” refers to a shape which is elongate in one direction, i.e., a shape which is longer in the one direction than in any other direction intersecting with the one direction. Thus, each of the plurality of metallic parts 31 is longer in the first direction D11 than in the second direction D12.

In the metal layer 3, the plurality of metallic parts 31 are arranged to be spaced from each other in the second direction D12 when viewed in plan in the thickness direction D10 defined with respect to the Ga₂O₃-based substrate 2 (refer to FIG. 2). That is to say, in the metal layer 3, the plurality of metallic parts 31 are arranged to be spaced from each other in a direction perpendicular to the plurality of metallic parts 31 when viewed in plan in the thickness direction D10 defined with respect to the Ga₂O₃-based substrate 2. In other words, in the metal layer 3, the plurality of metallic parts 31 are arranged in stripes when viewed in plan in the thickness direction D10 defined with respect to the Ga₂O₃-based substrate 2. Each of the plurality of metallic parts 31 may, but does not have to, have a thickness of 50 nm, for example.

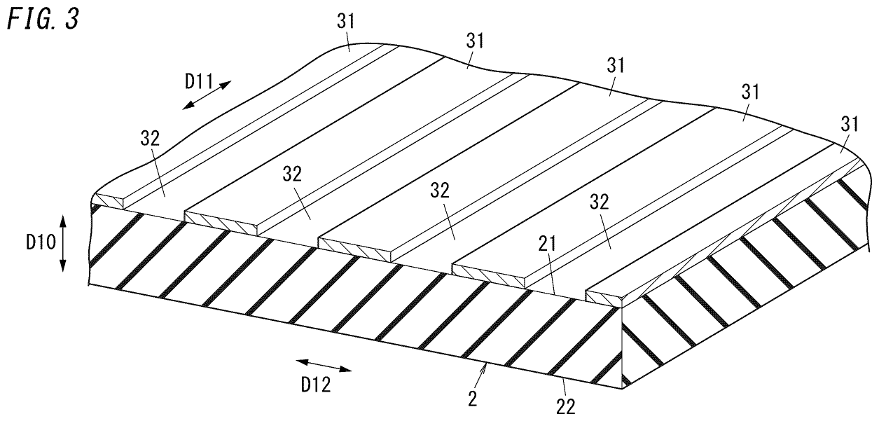

In the metal layer 3, the plurality of metallic parts 31 and the plurality of openings 32 are arranged alternately (refer to FIG. 3). Each of the plurality of openings 32 is open on both sides in the first direction D11. Alternatively, each of the plurality of openings 32 may also have a shape which is open on neither side in the first direction D11.

The β-Ga₂O₃ layer 4 is an epitaxial layer which has been grown epitaxially on the Ga₂O₃-based substrate 2 as a base member. More specifically, the β-Ga₂O₃ layer 4 is a β-Ga₂O₃ epitaxial layer which has been grown epitaxially on the β-Ga₂O₃ substrate 20. In the epitaxial wafer 1 according to the first embodiment, the β-Ga₂O₃ layer 4 is an n-type β-Ga₂O₃ layer. The n-type β-Ga₂O₃ layer contains an n-type impurity (such as Sn, Si, or Ge).

The β-Ga₂O₃ layer 4 covers the first principal surface 21 of the Ga₂O₃-based substrate 2 and the metal layer 3. More specifically, the β-Ga₂O₃ layer 4 covers not only multiple parts 211, not covered with the metal layer 3, of the first principal surface 21 of the Ga₂O₃-based substrate 2 but also the metal layer 3.

The thickness T2 of the β-Ga₂O₃ layer 4 is smaller than the thickness T1 of the Ga₂O₃-based substrate 2. The thickness T2 of the β-Ga₂O₃ layer 4 may be, for example, equal to or greater than 200 nm and equal to or less than 500 nm but may also be greater than 500 nm.

### (1.2) Method for Fabricating Epitaxial Wafer

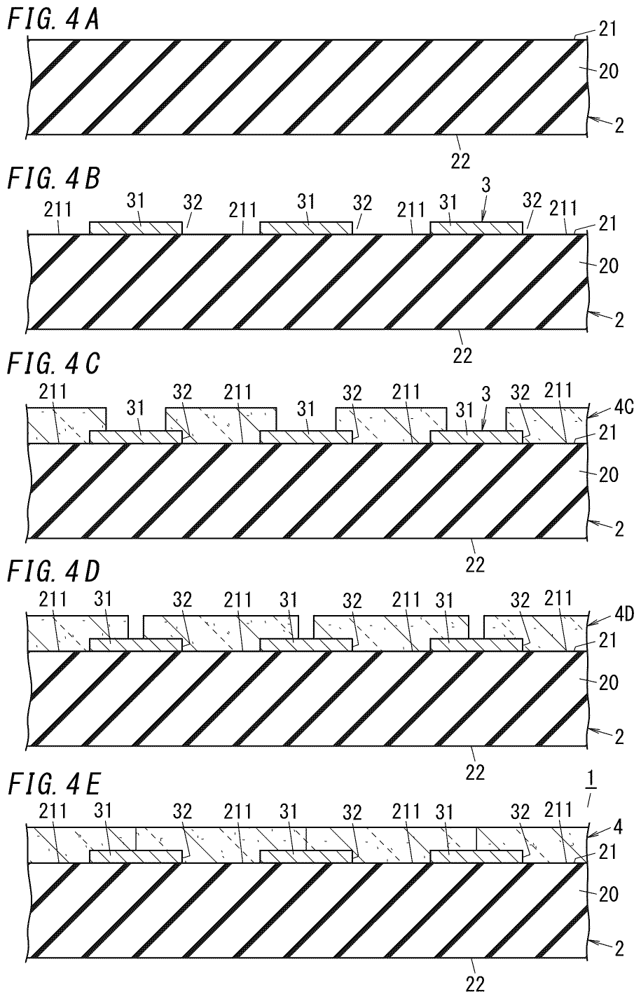

Next, a method for fabricating the epitaxial wafer 1 according to the first embodiment will be described with reference to FIG. 4A-4E.

A method for fabricating the epitaxial wafer 1 includes a substrate providing process step, a metal layer forming process step, and an epitaxial growing process step.

The substrate providing process step includes providing a Ga₂O₃-based substrate 2 having a first principal surface 21 and a second principal surface 22 opposite from the first principal surface 21 (refer to FIG. 4A).

The metal layer forming process step includes forming a metal layer 3 having a plurality of metallic parts 31 and a plurality of openings 32 on the first principal surface 21 of the Ga₂O₃-based substrate 2 (refer to FIG. 4B). That is to say, the metal layer forming process step includes forming a metal layer 3 in a predetermined pattern. The metal layer forming process step may include, for example, forming a metallic material layer, which will be patterned into the metal layer 3, by evaporation, for example, on the first principal surface 21 of the Ga₂O₃-based substrate 2, and then patterning the metallic material layer by, for example, photolithographic and etching techniques, thereby forming a metal layer 3 as respective parts of the metallic material layer. Alternatively, the metal layer forming process step may include forming the metal layer 3 by evaporation, for example, using a metal mask.

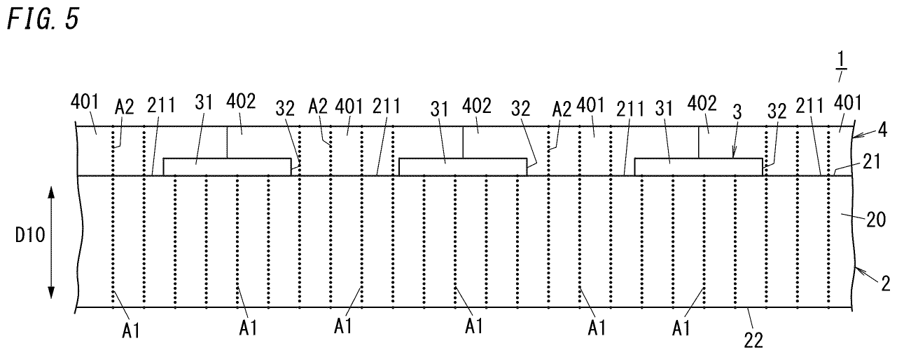

The epitaxial growing process step includes forming a β-Ga₂O₃ layer 4 by epitaxial lateral overgrowth (ELO) using a mist chemical vapor deposition (CVD) process to cover the first principal surface 21 of the Ga₂O₃-based substrate 2 and the metal layer 3 (refer to FIG. 4E). The epitaxial lateral overgrowth is a crystal growing technique as a combination of an epitaxial growth and a lateral overgrowth. That is to say, some parts of the β-Ga₂O₃ layer 4 are formed by epitaxial growth directly on the first principal surface 21 of the Ga₂O₃-based substrate 2, while the other parts of the β-Ga₂O₃ layer 4 are formed by lateral overgrowth on the metal layer 3. Those parts, formed directly on the first principal surface 21 of the Ga₂O₃-based substrate 2, of the β-Ga₂O₃ layer 4 include a plurality of first parts 401 (refer to FIG. 5) corresponding one to one to a plurality of areas 211, not covered with the metal layer 3, of the first principal surface 21 of the Ga₂O₃-based substrate 2. On the other hand, those parts, formed on the metal layer 3, of the β-Ga₂O₃ layer 4 include a plurality of parts 402 (refer to FIG. 5) corresponding one to one to the plurality of metallic parts 31. FIG. 4C illustrates a β-Ga₂O₃ layer 4C made up of respective parts of the β-Ga₂O₃ layer 4 while β-Ga₂O₃ crystals are growing epitaxially. FIG. 4D illustrates a β-Ga₂O₃ layer 4D made up of respective parts of the β-Ga₂O₃ layer 4 while β-Ga₂O₃ crystals are growing epitaxially. The β-Ga₂O₃ layer 4D is a β-Ga₂O₃ layer that has grown to an increased degree compared with the β-Ga₂O₃ layer 4C. That is to say, the β-Ga₂O₃ layer 4D is thicker than the β-Ga₂O₃ layer 4C and has a higher coverage with respect to each of the metallic parts 31 than the β-Ga₂O₃ layer 4C does. FIG. 4E illustrates a β-Ga₂O₃ layer 4 which covers the respective metallic parts 31 by combining respective β-Ga₂O₃ crystals that have overgrown laterally from both sides of each of the metallic parts 31 in the width direction (i.e., a direction parallel to the second direction D12). In the epitaxial growing process step, a mist CVD system is used as an epitaxial growing system. Optionally, in this epitaxial growing process step, a molecular beam epitaxy (MBE) method or a hydride vapor phase epitaxy (HVPE) method may be adopted instead of the mist CVD method.

As shown in FIG. 5, threading dislocations A1 of the Ga₂O₃-based substrate 2 are inherited as threading dislocations A2 of the β-Ga₂O₃ layer 4 in the plurality of first parts 401 of the β-Ga₂O₃ layer 4 in the epitaxial wafer 1, while the threading dislocations A1 of the Ga₂O₃-based substrate 2 are not inherited to the plurality of second parts 402. In the β-Ga₂O₃ layer 4, the dislocation density of each of the plurality of second parts 402 is lower than the dislocation density of any of the plurality of first parts 401. The dislocation density is a value obtained based on a cross-sectional transmission electron microscope (TEM) image.

### (2) β-Ga₂O₃-Based Device and Method for Fabricating the Same

### (2.1) β-Ga₂O₃-Based Device

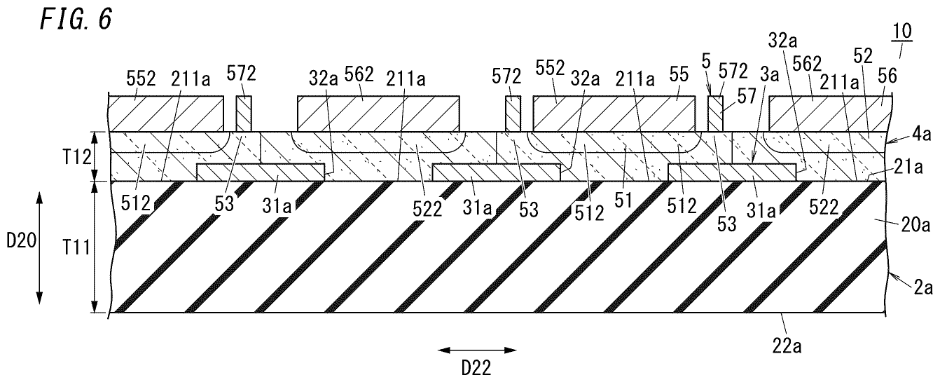

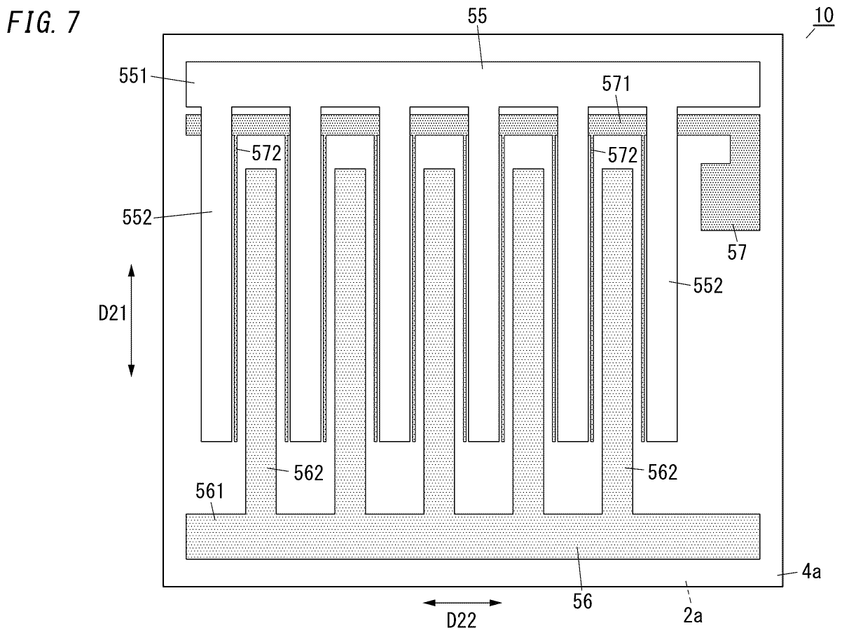

Next, a β-Ga₂O₃-based device 10 according to the first embodiment will be described with reference to FIGS. 6 and 7.

The β-Ga₂O₃-based device 10 according to the first embodiment includes a Ga₂O₃-based substrate 2a, a metal layer 3a, a β-Ga₂O₃ layer 4a, and a semiconductor element 5 as shown in FIG. 6. The β-Ga₂O₃-based device 10 is a chip (also called a “die”). The Ga₂O₃-based substrate 2a is, for example, a fragment of the Ga₂O₃-based substrate 2 of the epitaxial wafer 1 (refer to FIG. 1). In this embodiment, the thickness T11 of the Ga₂O₃-based substrate 2a is equal to the thickness T1 of the Ga₂O₃-based substrate 2. Alternatively, the thickness T11 of the Ga₂O₃-based substrate 2a may be smaller than the thickness T1 of the Ga₂O₃-based substrate 2.

The Ga₂O₃-based substrate 2a has a first principal surface 21a and a second principal surface 22a opposite from the first principal surface 21a.

The Ga₂O₃-based substrate 2a is a β-Ga₂O₃ substrate 20a. The β-Ga₂O₃ substrate 20a is made up of β-Ga₂O₃ single crystals. The crystal structure of the β-Ga₂O₃ single crystals is a monoclinic crystal system. The first principal surface 21a of the Ga₂O₃-based substrate 2a may be, but does not have to be, a (010) plane or a (001) plane of β-Ga₂O₃ single crystals, for example. In the β-Ga₂O₃-based device 10 according to the first embodiment, the β-Ga₂O₃ substrate 20a is a semi-insulating β-Ga₂O₃ substrate. The semi-insulating β-Ga₂O₃ substrate is a β-Ga₂O₃ substrate having a resistivity equal to or higher than 1×10⁸ Ωcm and equal to or lower than 1×10¹² Ωcm. The Ga₂O₃-based substrate 2a has a rectangular shape when viewed in plan in the thickness direction D20 defined with respect to the Ga₂O₃-based substrate 2a. The Ga₂O₃-based substrate 2a may have a thickness T11 equal to or greater than 400 μm and equal to or less than 800 μm, for example.

The metal layer 3a may be made of a material such as a noble metal or a refractory metal. If a noble metal is used as a material for the metal layer 3a, the noble metal may be Pt or Au, for example, but may also be any noble metal other than Pt and Au. If a refractory metal is used as a material for the metal layer 3a, the refractory metal may be Ta or W, for example, but may also be any refractory metal other than Ta and W.

The metal layer 3a is formed selectively on the first principal surface 21a of the Ga₂O₃-based substrate 2a.

The β-Ga₂O₃ layer 4a covers the first principal surface 21a of the Ga₂O₃-based substrate 2a and the metal layer 3a. More specifically, the β-Ga₂O₃ layer 4a covers not only multiple parts 211a, not covered with the metal layer 3a, of the first principal surface 21a of the Ga₂O₃-based substrate 2a but also the metal layer 3a.

The semiconductor element 5 includes at least a part of the β-Ga₂O₃ layer 4a. The semiconductor element 5 will be described later.

In the β-Ga₂O₃-based device 10 according to the first embodiment, the metal layer 3a includes a plurality of metallic parts 31a. Each of the plurality of metallic parts 31a has a linear shape. In the following description, the longitudinal axis of each of the plurality of metallic parts 31a is herein defined to be a first direction D21 and a direction perpendicular to both the thickness direction D20 defined with respect to the Ga₂O₃-based substrate 2a and the first direction D21 is herein defined to be a second direction D22. In the metal layer 3a, the plurality of metallic parts 31a are arranged to be spaced from each other in the second direction D22 when viewed in plan in the thickness direction D20 defined with respect to the Ga₂O₃-based substrate 2a. That is to say, in the metal layer 3a, the plurality of metallic parts 31a are arranged to be spaced from each other in a direction perpendicular to the plurality of metallic parts 31a (i.e., in the second direction D22) when viewed in plan in the thickness direction D20 defined with respect to the Ga₂O₃-based substrate 2a. In other words, in the metal layer 3a, the plurality of metallic parts 31a are arranged in stripes when viewed in plan in the thickness direction D20 defined with respect to the Ga₂O₃-based substrate 2a. Each of the plurality of metallic parts 31a may, but does not have to, have a thickness of 50 nm, for example.

In the metal layer 3a, the plurality of metallic parts 31a and the plurality of openings 32a are arranged alternately. Each of the plurality of openings 32a is open on both sides in the first direction D21. Alternatively, each of the plurality of openings 32a may also have a shape which is open on neither side in the first direction D21.

The β-Ga₂O₃ layer 4a is an epitaxial layer which has been grown epitaxially on the Ga₂O₃-based substrate 2a as a base member. More specifically, the β-Ga₂O₃ layer 4a is a β-Ga₂O₃ epitaxial layer which has been grown epitaxially on the β-Ga₂O₃ substrate 20a. In the β-Ga₂O₃-based device 10 according to the first embodiment, the β-Ga₂O₃ layer 4a is an n-type β-Ga₂O₃ layer. The n-type β-Ga₂O₃ layer contains an n-type impurity (such as Sn, Si, or Ge). In the following description, the β-Ga₂O₃ layer 4a will be hereinafter sometimes referred to as an “n-type β-Ga₂O₃ layer 4a.”

The thickness T12 of the β-Ga₂O₃ layer 4a is smaller than the thickness T11 of the Ga₂O₃-based substrate 2a. The thickness T12 of the β-Ga₂O₃ layer 4a may be, for example, equal to or greater than 200 nm and equal to or less than 500 nm but may also be greater than 500 nm.

In the β-Ga₂O₃ layer 4a, the dislocation density of its parts overlapping with the metallic parts 31a in the thickness direction D20 defined with respect to the Ga₂O₃-based substrate 2a (i.e., its parts formed on the metallic parts 31a) is smaller than the dislocation density of its parts not overlapping with the metallic parts 31a in the thickness direction D20 defined with respect to the Ga₂O₃-based substrate 2a (i.e., its parts formed directly on the Ga₂O₃-based substrate 2a).

In the β-Ga₂O₃-based device 10 according to the first embodiment, the semiconductor element 5 is a metal semiconductor field effect transistor (MESFET).

The semiconductor element 5 includes a drain region 51, a source region 52, a drain electrode 55, a source electrode 56, and a gate electrode 57 as shown in FIGS. 6 and 7. Note that although the source electrode 56 and the gate electrode 57 are shaded by dotted hatching in FIG. 7, the hatching does not indicate a cross section but is adopted to make the elements on the drawing easily recognizable.

The drain region 51 is configured as an n⁺-type β-Ga₂O₃ region defined in the n-type β-Ga₂O₃ layer 4a. The drain region 51 has a comb shape when viewed in plan in the thickness direction D20 defined with respect to the Ga₂O₃-based substrate 2a. The drain region 51 includes: a drain region comb backbone having an elongate shape and a longitudinal axis defined by the second direction D22; and a plurality of drain region comb teeth 512 extending in the first direction D21 from the drain region comb backbone. The carrier concentration in the n⁺-type β-Ga₂O₃ region serving as the drain region 51 is higher than the carrier concentration in the n-type β-Ga₂O₃ layer 4a.

The source region 52 is configured as an n⁺-type β-Ga₂O₃ region defined in the n-type β-Ga₂O₃ layer 4a. The source region 52 has a comb shape when viewed in plan in the thickness direction D20 defined with respect to the Ga₂O₃-based substrate 2a. The source region 52 includes: a source region comb backbone having an elongate shape and a longitudinal axis defined by the second direction D22; and a plurality of source region comb teeth 522 extending in the first direction D21 from the source region comb backbone. The carrier concentration in the n⁺-type β-Ga₂O₃ region serving as the source region 52 is higher than the carrier concentration in the n-type β-Ga₂O₃ layer 4a.

The channel forming region 53 is defined in a region, located between the drain region 51 and the source region 52, of the n-type β-Ga₂O₃ layer 4a. More specifically, the channel forming region 53 is defined between the drain region comb tooth 512 and the source region comb tooth 522 which are adjacent to each other in the second direction D22.

The drain electrode 55 is formed on the drain region 51. The drain electrode 55 overlaps with the drain region 51 when viewed in plan in the thickness direction D20 defined with respect to the Ga₂O₃-based substrate 2a. The drain electrode 55 has a comb shape when viewed in plan in the thickness direction D20 defined with respect to the Ga₂O₃-based substrate 2a (refer to FIG. 7). The drain electrode 55 includes: a drain electrode comb backbone 551 having an elongate shape and a longitudinal axis defined by the second direction D22; and a plurality of drain electrode comb teeth 552 extending in the first direction D21 from the drain electrode comb backbone 551 as shown in FIG. 7. The plurality of drain electrode comb teeth 552 correspond one to one to the plurality of drain region comb teeth 512. Each of the plurality of drain electrode comb teeth 552 overlaps with a corresponding one of the plurality of drain region comb teeth 512 when viewed in plan in the thickness direction D20 defined with respect to the Ga₂O₃-based substrate 2a. A material for the drain electrode 55 may be Au or Pt, for example, but may also be a metal other than Au and Pt or an alloy. The drain electrode 55 is electrically connected to the drain region 51. As used herein, the expression “the drain electrode 55 is electrically connected to the drain region 51” means that the drain electrode 55 and the drain region 51 make ohmic contact with each other.

The source electrode 56 is formed on the source region 52. The source electrode 56 overlaps with the source region 52 when viewed in plan in the thickness direction D20 defined with respect to the Ga₂O₃-based substrate 2a. The source electrode 56 has a comb shape when viewed in plan in the thickness direction D20 defined with respect to the Ga₂O₃-based substrate 2a (refer to FIG. 7). The source electrode 56 includes: a source electrode comb backbone 561 having an elongate shape and a longitudinal axis defined by the second direction D22; and a plurality of source electrode comb teeth 562 extending in the first direction D21 from the source electrode comb backbone 561. The plurality of source electrode comb teeth 562 correspond one to one to the plurality of source region comb teeth 522. Each of the plurality of source electrode comb teeth 562 overlaps with a corresponding one of the plurality of source region comb teeth 522 when viewed in plan in the thickness direction D20 defined with respect to the Ga₂O₃-based substrate 2a. A material for the source electrode 56 may be Au or Pt, for example, but may also be a metal other than Au and Pt or an alloy. The source electrode 56 is electrically connected to the source region 52. As used herein, the expression “the source electrode 56 is electrically connected to the source region 52” means that the source electrode 56 and the source region 52 make ohmic contact with each other.

In the semiconductor element 5, the drain electrode comb backbone 551 and the source electrode comb backbone 561 face each other in the first direction D21. Also, in the semiconductor element 5, the plurality of drain electrode comb teeth 552 and the plurality of source electrode comb teeth 562 are arranged to be spaced from each other in the second direction D22.

The gate electrode 57 is formed on the n-type β-Ga₂O₃ layer 4a. The gate electrode 57 has a comb shape when viewed in plan in the thickness direction D20 defined with respect to the Ga₂O₃-based substrate 2a (refer to FIG. 7). The gate electrode 57 includes: a gate electrode comb backbone 571 having an elongate shape and a longitudinal axis defined by the second direction D22; and a plurality of gate electrode comb teeth 572 extending in the first direction D21 from the gate electrode comb backbone 571. A material for the gate electrode 57 may be Au or Pt, for example. Alternatively, the material for the gate electrode 57 may also be a metal other than Au or Pt or an alloy.

In the semiconductor element 5, the plurality of drain electrode comb teeth 552, the plurality of gate electrode comb teeth 572, and the plurality of source electrode comb teeth 562 are arranged side by side in the second direction D22. Thus, each gate electrode comb tooth 572 is located between a drain electrode comb tooth 552 and a source electrode comb tooth 562 which are adjacent to each other in the second direction D22. The plurality of gate electrode comb teeth 572 correspond one to one to the plurality of channel forming regions 53 in the n-type β-Ga₂O₃ layer 4a. Each of the plurality of channel forming regions 53 is a region between a drain region comb tooth 512 and a source region comb tooth 522 which are adjacent to each other in the second direction D22 inside the n-type β-Ga₂O₃ layer 4a. Each of the plurality of gate electrode comb teeth 572 overlaps with a corresponding one of the plurality of channel forming regions 53 when viewed in plan in the thickness direction D20 defined with respect to the Ga₂O₃-based substrate 2a. The semiconductor element 5 includes an interlevel dielectric film interposed between the gate electrode comb backbone 571 and the plurality of drain electrode comb teeth 552 to prevent the gate electrode 57 from making contact with the drain electrode 55.

Each of the plurality of gate electrode comb teeth 572 overlaps with any one metallic part 31a out of the plurality of metallic parts 31a when viewed in plan in the thickness direction D20 defined with respect to the Ga₂O₃-based substrate 2a. None of the plurality of gate electrode comb teeth 572 overlap with any of the plurality of parts 211a of the first principal surface 21a of the Ga₂O₃-based substrate 2a when viewed in plan in the thickness direction D20 defined with respect to the Ga₂O₃-based substrate 2a. In the semiconductor element 5 according to the first embodiment, the plurality of gate electrode comb teeth 572 correspond one to one to the plurality of metallic parts 31a. However, this is only an example and should not be construed as limiting. The plurality of gate electrode comb teeth 572 does not have to correspond one to one to the plurality of metallic parts 31a. Each of the plurality of channel forming regions 53 overlaps with any one metallic part 31a out of the plurality of metallic parts 31a but none of the plurality of channel forming regions 53 overlap with any of the plurality of parts 211a of the first principal surface 21a of the Ga₂O₃-based substrate 2a when viewed in plan in the thickness direction D20 defined with respect to the Ga₂O₃-based substrate 2a.

Each of the plurality of gate electrode comb teeth 572 is arranged to be offset in the second direction D22 to avoid overlapping with the center of a corresponding one of the plurality of metallic parts 31a in the second direction D22 when viewed in plan in the thickness direction D20 defined with respect to the Ga₂O₃-based substrate 2a. In the semiconductor element 5, the shortest distance between a gate electrode comb tooth 572 and a drain electrode comb tooth 552 which are adjacent to each other in the second direction D22 is shorter than the distance between the gate electrode comb tooth 572 and a source electrode comb tooth 562 which are adjacent to each other in the second direction D22.

### (2.2) Method for Fabricating β-Ga₂O₃-Based Device

Next, an exemplary method for fabricating the β-Ga₂O₃-based device 10 will be described briefly with reference to FIG. 4A-4E. As for the same process steps as those of the method for fabricating the epitaxial wafer 1, the description thereof will be omitted as appropriate herein.

The method for fabricating the β-Ga₂O₃-based device 10 includes a substrate providing process step, a metal layer forming process step, an epitaxial growing process step, a drain/source region forming process step, an electrode forming process step, and a dicing process step.

The substrate providing process step includes providing a Ga₂O₃-based substrate 2 having a first principal surface 21 and a second principal surface 22 opposite from the first principal surface 21 (refer to FIG. 4A). The Ga₂O₃-based substrate 2 is a wafer configured as a β-Ga₂O₃ substrate 20 and is a wafer as a prototype of the Ga₂O₃-based substrate 2a.

The metal layer forming process step includes forming a metal layer 3 having a plurality of metallic parts 31 and a plurality of openings 32 on the first principal surface 21 of the Ga₂O₃-based substrate 2 (refer to FIG. 4B). The plurality of metallic parts 31 and the plurality of opening 32 will be the plurality of metallic parts 31a and the plurality of openings 32a, respectively. The width of each of the plurality of metallic parts 31 as measured in the second direction D12 is equal to the width of a corresponding one of the plurality of metallic parts 31a as measured in the second direction D22. On the other hand, the length of each of the plurality of metallic parts 31 as measured in the first direction D11 is greater than the length of a corresponding one of the plurality of metallic parts 31a as measured in the first direction D21. The width of each of the plurality of openings 32 as measured in the second direction D12 is equal to the width of a corresponding one of the plurality of openings 32a as measured in the second direction D22. On the other hand, the length of each of the plurality of openings 32 as measured in the first direction D11 is greater than the length of a corresponding one of the plurality of openings 32a as measured in the first direction D21.

The epitaxial growing process step includes forming a β-Ga₂O₃ layer 4 by epitaxial lateral overgrowth using a mist CVD method to cover the first principal surface 21 of the Ga₂O₃-based substrate 2 and the metal layer 3 (refer to FIG. 4E). In this embodiment, the β-Ga₂O₃ layer 4 is an n-type β-Ga₂O₃ layer, which is a prototype of the β-Ga₂O₃ layer 4a. Alternatively, in the epitaxial growing process step, an MBE method or an HVPE method, for example, may be adopted instead of the mist CVD method.

The drain/source region forming process step includes forming a plurality of drain regions 51 (refer to FIG. 6) and a plurality of source regions 52 (refer to FIG. 6) in the β-Ga₂O₃ layer 4 by, for example, ion implantation and diffusion techniques.

The electrode forming process step includes forming the drain electrode 55, the source electrode 56, and the gate electrode 57 by evaporation, for example.

According to this method for fabricating the β-Ga₂O₃-based device 10, a wafer including a plurality of β-Ga₂O₃-based devices 10 may be obtained by performing the respective process steps from the substrate providing process step through the electrode forming process step. According to the method for fabricating the β-Ga₂O₃-based device 10, a plurality of β-Ga₂O₃-based devices 10 may be obtained by cutting off, in the dicing process step, the wafer including a plurality of β-Ga₂O₃-based devices 10 using a dicing saw or a laser dicing device, for example.

### (3) Advantages

An epitaxial wafer 1 according to the first embodiment includes a Ga₂O₃-based substrate 2, a metal layer 3, and a β-Ga₂O₃ layer 4. The Ga₂O₃-based substrate 2 has a first principal surface 21 and a second principal surface 22 opposite from the first principal surface 21. The metal layer 3 is formed on the first principal surface 21 of the Ga₂O₃-based substrate 2. The metal layer 3 has a plurality of openings 32. The β-Ga₂O₃ layer 4 covers the first principal surface 21 of the Ga₂O₃-based substrate 2 and the metal layer 3. The metal layer 3 is made of a material such as a noble metal or a refractory metal. The thickness T2 of the β-Ga₂O₃ layer 4 is smaller than the thickness T1 of the Ga₂O₃-based substrate 2.

The epitaxial wafer 1 according to the first embodiment, having such a configuration, may contribute to improving the characteristics of a β-Ga₂O₃-based device 10. More specifically, in the epitaxial wafer 1 according to the first embodiment, the dislocation density of each of a plurality of second parts 402, corresponding one to one to the plurality of metallic parts 31, of the β-Ga₂O₃ layer 4 is smaller than the dislocation density of each of a plurality of first parts 401, formed directly on the first principal surface 21 of the Ga₂O₃-based substrate 2, of the β-Ga₂O₃ layer 4. Thus, as for the β-Ga₂O₃-based device 10 to be fabricated using the epitaxial wafer 1, laying out functional regions, which are easily subject to the effect of dislocations, of the β-Ga₂O₃-based device 10 on those parts, covering the metal layer 3, of the β-Ga₂O₃ layer 4 allows for contributing to improving the characteristics of the β-Ga₂O₃-based device 10. Those functional regions may be, for example, channel forming regions 53 which are important in determining the characteristics of MESFETs serving as semiconductor elements 5.

In addition, in the epitaxial wafer 1 according to the first embodiment, the threading dislocations A1 of the Ga₂O₃-based substrate 2 are unlikely to be inherited to those parts (i.e., the respective second parts 402), covering the metal layer 3, of the β-Ga₂O₃ layer 4, thus allowing a less expensive β-Ga₂O₃ substrate 20 to be used as the Ga₂O₃-based substrate 2 and thereby contributing to cutting down the cost.

Furthermore, in the epitaxial wafer 1 according to the first embodiment, the β-Ga₂O₃ layer 4 covers the first principal surface 21 of the Ga₂O₃-based substrate 2 and the metal layer 3. Thus, in the epitaxial wafer 1, the metal layer 3 is interposed between parts of the β-Ga₂O₃ layer 4 and the first principal surface 21 of the Ga₂O₃-based substrate 2. This allows for reducing the effect on those parts, formed on the metal layer 3, of the β-Ga₂O₃ layer 4 when the Ga₂O₃-based substrate 2 is polished from the second principal surface 22 to have its thickness reduced. Thus, the epitaxial wafer 1 makes it easier to reduce the thickness T1 of the Ga₂O₃-based substrate 2. Consequently, this enables the thermal resistance of the β-Ga₂O₃-based device 10 fabricated using the epitaxial wafer 1 to be reduced, thus allowing for improving the characteristics of the β-Ga₂O₃-based device 10.

A β-Ga₂O₃-based device 10 according to the first embodiment includes a Ga₂O₃-based substrate 2a, a metal layer 3a, a β-Ga₂O₃ layer 4a, and a semiconductor element 5. The Ga₂O₃-based substrate 2a has a first principal surface 21a and a second principal surface 22a opposite from the first principal surface 21a. The metal layer 3a is formed selectively on the first principal surface 21a of the Ga₂O₃-based substrate 2a. The β-Ga₂O₃ layer 4a covers the first principal surface 21a of the Ga₂O₃-based substrate 2a and the metal layer 3a. The semiconductor element 5 includes at least a part of the β-Ga₂O₃ layer 4a. The metal layer 3a is made of a material such as a noble metal or a refractory metal. The thickness T12 of the β-Ga₂O₃ layer 4a is smaller than the thickness T11 of the Ga₂O₃-based substrate 2a.

The β-Ga₂O₃-based device 10 according to the first embodiment, having such a configuration, may contribute to improving the characteristics.

In the β-Ga₂O₃-based device 10 according to the first embodiment, the semiconductor element 5 is a MESFET including a drain region 51, a source region 52, a channel forming region 53, a drain electrode 55, a source electrode 56, and a gate electrode 57. The drain region 51, the source region 52, and the channel forming region 53 are defined in the β-Ga₂O₃ layer 4a. The channel forming region 53 overlaps with one metallic part 31a out of the plurality of metallic parts 31a when viewed in plan in the thickness direction D20 defined with respect to the Ga₂O₃-based substrate 2a.

The β-Ga₂O₃-based device 10 according to the first embodiment, having such a configuration, may contribute to improving the characteristics of the MESFET.

A method for fabricating a β-Ga₂O₃-based device 10 according to the first embodiment includes a substrate providing process step, a metal layer forming process step, and an epitaxial growing process step. The substrate providing process step includes providing a Ga₂O₃-based substrate 2 having a first principal surface 21 and a second principal surface 22 opposite from the first principal surface 21. The metal layer forming process step includes forming a metal layer 3 having a plurality of openings 32 on the first principal surface 21 of the Ga₂O₃-based substrate 2. The epitaxial growing process step includes forming a β-Ga₂O₃ layer 4 that covers the first principal surface 21 of the Ga₂O₃-based substrate 2 and the metal layer 3 by epitaxial lateral overgrowth using a mist CVD method. The metal layer 3 is made of a material such as a noble metal or a refractory metal. The thickness T2 of the β-Ga₂O₃ layer 4 is smaller than the thickness T1 of the Ga₂O₃-based substrate 2.

This method for fabricating a β-Ga₂O₃-based device 10 according to the first embodiment may contribute to improving the characteristics of the β-Ga₂O₃-based device 10.

### Variation of First Embodiment

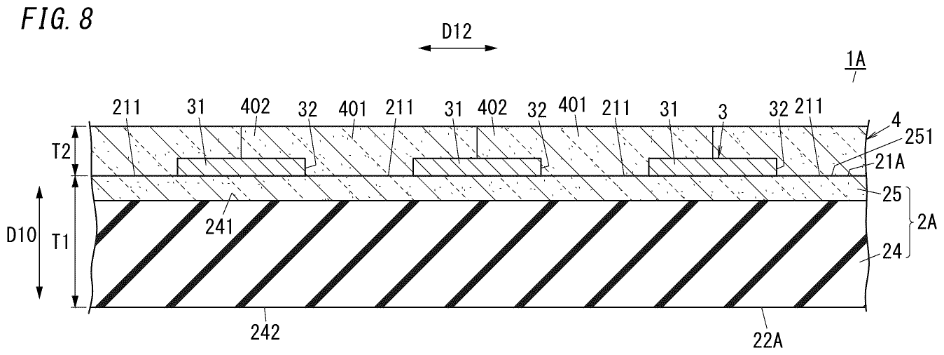

An epitaxial wafer 1A according to a variation of the first embodiment will be described with reference to FIG. 8. In the following description, any constituent element of the epitaxial wafer 1A according to this variation, having the same function as a counterpart of the epitaxial wafer 1 (refer to FIGS. 1 and 2) according to the first embodiment described above, will be designated by the same reference numeral as that counterpart's, and description thereof will be omitted as appropriate herein.

### (1) Epitaxial Wafer

The epitaxial wafer 1A according to this variation includes a Ga₂O₃-based substrate 2A instead of the Ga₂O₃-based substrate 2 of the epitaxial wafer 1 according to the first embodiment, which is a difference from the epitaxial wafer 1 according to the first embodiment described above.

The Ga₂O₃-based substrate 2A includes a sapphire substrate 24 and a β-Ga₂O₃ layer 25 formed on the sapphire substrate 24. In the Ga₂O₃-based substrate 2A, the surface 251 of the β-Ga₂O₃ layer 25 serves as the first principal surface 21A of the Ga₂O₃-based substrate 2A. The Ga₂O₃-based substrate 2A has a substantially circular shape when viewed in plan in the thickness direction D10 defined with respect to the Ga₂O₃-based substrate 2A.

In the Ga₂O₃-based substrate 2A, the thickness of the β-Ga₂O₃ layer 25 is smaller than the thickness of the sapphire substrate 24. The sapphire substrate 24 may have a thickness equal to or greater than 430 μm and equal to or less than 1300 μm, for example. The β-Ga₂O₃ layer 25 may have a thickness equal to or greater than 0.2 μm and equal to or less than 3 μm, for example.

The sapphire substrate 24 has a first principal surface 241 and a second principal surface 242 opposite from the first principal surface 241. The first principal surface 241 of the sapphire substrate 24 may be, but does not have to be, a c-plane. Alternatively, the first principal surface 241 of the sapphire substrate 24 may also be an m-plane. The c-plane is a (0001) plane. The m-plane may be a (1010) plane, for example. As used herein, each of the (0001) and (1010) planes is a crystallographic plane expressed by four Miller indices placed in parentheses. In the Ga₂O₃-based substrate 2A, the second principal surface 242 of the sapphire substrate 24 serves as the second principal surface 22A of the Ga₂O₃-based substrate 2A.

In the epitaxial wafer 1A, the thickness T2 of the β-Ga₂O₃ layer 4 is smaller than the thickness T1 of the Ga₂O₃-based substrate 2A.

In the β-Ga₂O₃ layer 4 of the epitaxial wafer 1A according to the first variation, the dislocation density of each of a plurality of second parts 402, corresponding one to one to the plurality of metallic parts 31, of the β-Ga₂O₃ layer 4 is smaller in the thickness direction D10 defined with respect to the Ga₂O₃-based substrate 2A than the dislocation density of any of a plurality of first parts 401, formed directly on the plurality of parts 211 of the first principal surface 21A of the Ga₂O₃-based substrate 2A, of the β-Ga₂O₃ layer 4.

### (2) Method for Fabricating Epitaxial Wafer

A method for fabricating the epitaxial wafer 1A, as well as the method for fabricating the epitaxial wafer 1, also includes a substrate providing process step, a metal layer forming process step, and an epitaxial growing process step.

In the method for fabricating the epitaxial wafer 1A, the substrate providing process step includes providing a sapphire substrate 24, epitaxially growing an α-Ga₂O₃ layer thereafter on the first principal surface 241 of the sapphire substrate 24 by a mist CVD method, and then annealing the α-Ga₂O₃ layer, thereby changing the crystal structure of the α-Ga₂O₃ layer to form a β-Ga₂O₃ layer 25. That is to say, the α-Ga₂O₃ layer is transformed into the β-Ga₂O₃ layer 25. In this manner, a Ga₂O₃-based substrate 2A is obtained. Alternatively, the substrate providing process step may include epitaxially growing a β-Ga₂O₃ layer 25 on the first principal surface 241 of the sapphire substrate 24 by a mist CVD method, of which the growing temperature is set at higher temperature than in a situation where the α-Ga₂O₃ layer is epitaxially grown on the first principal surface 241 of the sapphire substrate 24 by a mist CVD method.

The metal layer forming process step includes forming a metal layer 3 having a plurality of metallic parts 31 and a plurality of openings 32 on the first principal surface 21A of the Ga₂O₃-based substrate 2A.

The epitaxial growing process step includes forming a β-Ga₂O₃ layer 4 by epitaxial lateral overgrowth using a mist CVD method to cover the first principal surface 21A of the Ga₂O₃-based substrate 2A and the metal layer 3. Optionally, in the epitaxial growing process step, an MBE method or an HVPE method may be adopted instead of the mist CVD method.

### (3) β-Ga₂O₃-Based Device

The β-Ga₂O₃-based device according to this variation has substantially the same configuration as the β-Ga₂O₃-based device 10 according to the first embodiment described above. In the β-Ga₂O₃-based device according to this variation, the Ga₂O₃-based substrate 2a of the β-Ga₂O₃-based device 10 according to the first embodiment is made up of a sapphire substrate which forms part of the sapphire substrate 24 and a β-Ga₂O₃ layer formed on the sapphire substrate which forms part of the β-Ga₂O₃ layer 25, which is a difference from the β-Ga₂O₃-based device 10 according to the first embodiment.

### (4) Method for Fabricating β-Ga₂O₃-Based Device

A method for fabricating the β-Ga₂O₃-based device according to this variation is substantially the same as the method for fabricating the β-Ga₂O₃-based device 10 according to the first embodiment but is different from the latter method in that the substrate providing process step includes providing the epitaxial wafer 1A instead of the epitaxial wafer 1.

### (5) Advantages

The epitaxial wafer 1A according to this variation, as well as the epitaxial wafer 1 according to the first embodiment, may contribute to improving the characteristics of the β-Ga₂O₃-based device 10.

In addition, the epitaxial wafer 1A according to this variation may use the sapphire substrate 24 which is less expensive than the β-Ga₂O₃ substrate 20 of the epitaxial wafer 1, thus contributing to cutting down the cost compared to the epitaxial wafer 1.

### Second Embodiment

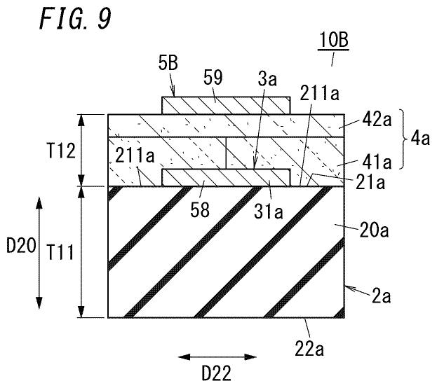

Next, a β-Ga₂O₃-based device 10B according to a second embodiment and a method for fabricating the β-Ga₂O₃-based device 10B will be described with reference to FIG. 9-12. In the following description, any constituent element of the β-Ga₂O₃-based device 10B according to this second embodiment, having the same function as a counterpart of the β-Ga₂O₃-based device 10 (refer to FIGS. 6 and 7) according to the first embodiment described above, will be designated by the same reference numeral as that counterpart's, and description thereof will be omitted as appropriate herein.

### (1) β-Ga₂O₃-Based Device

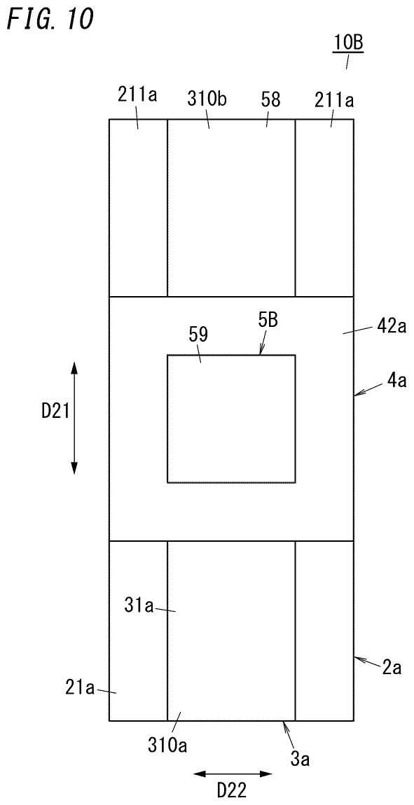

A β-Ga₂O₃-based device 10B according to the second embodiment will be described with reference to FIGS. 9 and 10.

The β-Ga₂O₃-based device 10B according to the second embodiment includes a Ga₂O₃-based substrate 2a, a metal layer 3a, a β-Ga₂O₃ layer 4a, and a semiconductor element 5B.

The Ga₂O₃-based substrate 2a has a first principal surface 21a and a second principal surface 22a opposite from the first principal surface 21a.

The Ga₂O₃-based substrate 2a is a β-Ga₂O₃ substrate 20a. Also, the β-Ga₂O₃ substrate 20a is a semi-insulating β-Ga₂O₃ substrate. The Ga₂O₃-based substrate 2a has a rectangular shape when viewed in plan in the thickness direction D20 defined with respect to the Ga₂O₃-based substrate 2a.

The metal layer 3a may be made of a material such as a noble metal or a refractory metal. If a noble metal is used as a material for the metal layer 3a, the noble metal may be Pt or Au, for example, but may also be any noble metal other than Pt and Au. If a refractory metal is used as a material for the metal layer 3a, the refractory metal may be Ta or W, for example, but may also be any refractory metal other than Ta and W.

The metal layer 3a is formed selectively on the first principal surface 21a of the Ga₂O₃-based substrate 2a.

The β-Ga₂O₃ layer 4a covers a part of the first principal surface 21a of the Ga₂O₃-based substrate 2a and a part of the metal layer 3a. More specifically, the β-Ga₂O₃ layer 4a covers not only each of two parts 211a, not covered with the metal layer 3a, of the first principal surface 21a of the Ga₂O₃-based substrate 2a partially but also the metal layer 3a partially.

The semiconductor element 5B includes at least a part of the β-Ga₂O₃ layer 4a. The semiconductor element 5B will be described later.

In the β-Ga₂O₃-based device 10B, the metal layer 3a includes one metallic part 31a. The metallic part 31a has a linear (elongate) shape. In the following description, the longitudinal axis of the metallic part 31a is herein defined to be a first direction D21 (refer to FIG. 10) and a direction perpendicular to both the thickness direction D20 defined with respect to the Ga₂O₃-based substrate 2a and the first direction D21 is herein defined to be a second direction D22.

The metallic part 31a is located between the two parts 211a of the first principal surface 21a of the Ga₂O₃-based substrate 2a when viewed in plan in the thickness direction D20 defined with respect to the Ga₂O₃-based substrate 2a. The metallic part 31a has a first end 310a and a second end 310b in the first direction D21. In the β-Ga₂O₃-based device 10B, neither the first end 310a nor the second end 310b of the metallic part 31a is covered with the β-Ga₂O₃ layer 4a.

The β-Ga₂O₃ layer 4a is an epitaxial layer which has been grown epitaxially on the Ga₂O₃-based substrate 2a as a base member.

The β-Ga₂O₃ layer 4a includes: an n⁺-type β-Ga₂O₃ layer 41a that covers a part of the first principal surface 21a of the Ga₂O₃-based substrate 2a and a part of the metal layer 3a; and an n-type β-Ga₂O₃ layer 42a formed on the n⁺-type β-Ga₂O₃ layer 41a.

Each of the n⁺-type β-Ga₂O₃ layer 41a and the n-type β-Ga₂O₃ layer 42a contains an n-type impurity (such as Sn, Si, or Ge). The carrier concentration in the n⁺-type β-Ga₂O₃ layer 41a is higher than the carrier concentration in the n-type β-Ga₂O₃ layer 42a. The n⁺-type β-Ga₂O₃ layer 41a makes an ohmic contact with the metal layer 3a.

The semiconductor element 5B is a Schottky barrier diode.

The semiconductor element 5B includes: a first metal electrode layer 58 formed out of the metal layer 3a; the n⁺-type β-Ga₂O₃ layer 41a; the n-type β-Ga₂O₃ layer 42a; and a second metal electrode layer 59. The second metal electrode layer 59 is formed on, and makes a Schottky contact with, the n-type β-Ga₂O₃ layer 42a.

In the semiconductor element 5B, the entire second metal electrode layer 59 overlaps with a part of the first metal electrode layer 58 when viewed in plan in the thickness direction D20 defined with respect to the Ga₂O₃-based substrate 2a.

In the semiconductor element 5B, the second metal electrode layer 59 serves as an anode electrode, while the n⁺-type β-Ga₂O₃ layer 41a and the first metal electrode layer 58 serve as a cathode electrode. In the semiconductor element 5B, the first end 310a and second end 310b of the metallic part 31a serving as the first metal electrode layer 58 may be used as electrode pads of the cathode electrode.

### (2) Method for Fabricating β-Ga₂O₃-Based Device

Next, an exemplary method for fabricating the β-Ga₂O₃-based device 10B will be described briefly with reference to FIGS. 4A, 4B, 11, and 12. As for the same process steps as those of the method for fabricating the β-Ga₂O₃-based device 10 according to the first embodiment, the description thereof will be omitted as appropriate herein.

The method for fabricating the β-Ga₂O₃-based device 10B includes a substrate providing process step, a metal layer forming process step, an epitaxial growing process step, an electrode layer forming process step, a patterning process step, and a dicing process step.

The substrate providing process step includes providing a Ga₂O₃-based substrate 2 having a first principal surface 21 and a second principal surface 22 opposite from the first principal surface 21 (refer to FIG. 4A). The Ga₂O₃-based substrate 2 is a wafer configured as a β-Ga₂O₃ substrate 20 and is a wafer as a prototype of the Ga₂O₃-based substrate 2a.

The metal layer forming process step includes forming a metal layer 3 having a plurality of metallic parts 31 and a plurality of openings 32 on the first principal surface 21 of the Ga₂O₃-based substrate 2 (refer to FIG. 4B). Each of the plurality of metallic parts 31 will be the metallic part 31a. The width of each of the plurality of metallic parts 31 is equal to the width of the metallic part 31a as measured in the second direction D22 (refer to FIG. 10). On the other hand, the length of each of the plurality of metallic parts 31 is greater than the length of the metallic part 31a as measured in the first direction D21 (refer to FIG. 10).

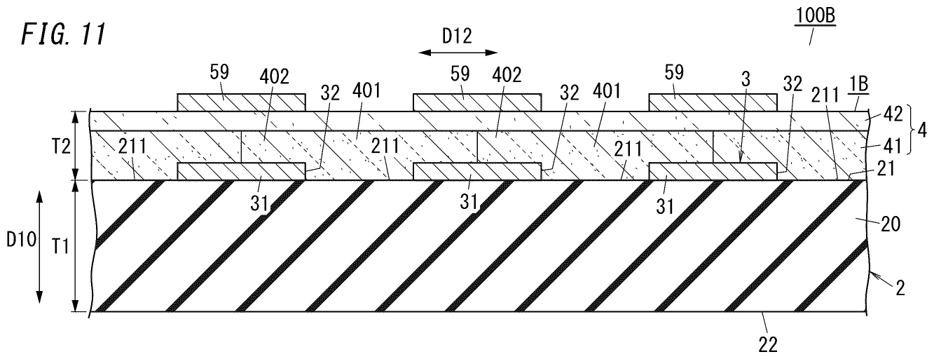

The epitaxial growing process step includes forming an n⁺-type β-Ga₂O₃ layer 41 (refer to FIG. 11) by epitaxial lateral overgrowth using a mist CVD method to cover the first principal surface 21 of the Ga₂O₃-based substrate 2 and the metal layer 3 and forming an n-type β-Ga₂O₃ layer 42 (refer to FIG. 11) by a mist CVD method to cover the n⁺-type β-Ga₂O₃ layer 41. The n⁺-type β-Ga₂O₃ layer 41 is a prototype of the n⁺-type β-Ga₂O₃ layer 41a. The n-type β-Ga₂O₃ layer 42 is a prototype of the n-type β-Ga₂O₃ layer 42a. An epitaxial wafer 1B (refer to FIG. 11) is fabricated by performing the substrate providing process step, the metal layer forming process step, and the epitaxial growing process step. Alternatively, in the epitaxial growing process step, an MBE method or an HVPE method, for example, may be adopted instead of the mist CVD method. In this embodiment, the n⁺-type β-Ga₂O₃ layer 41 and the n-type β-Ga₂O₃ layer 42 form the β-Ga₂O₃ layer 4.

The electrode layer forming process step includes forming a plurality of second metal electrode layers 59 (refer to FIG. 11) by evaporation, for example. Note that the electrode layer forming process step includes forming a plurality of second metal electrode layers 59 on the β-Ga₂O₃ layer 4.

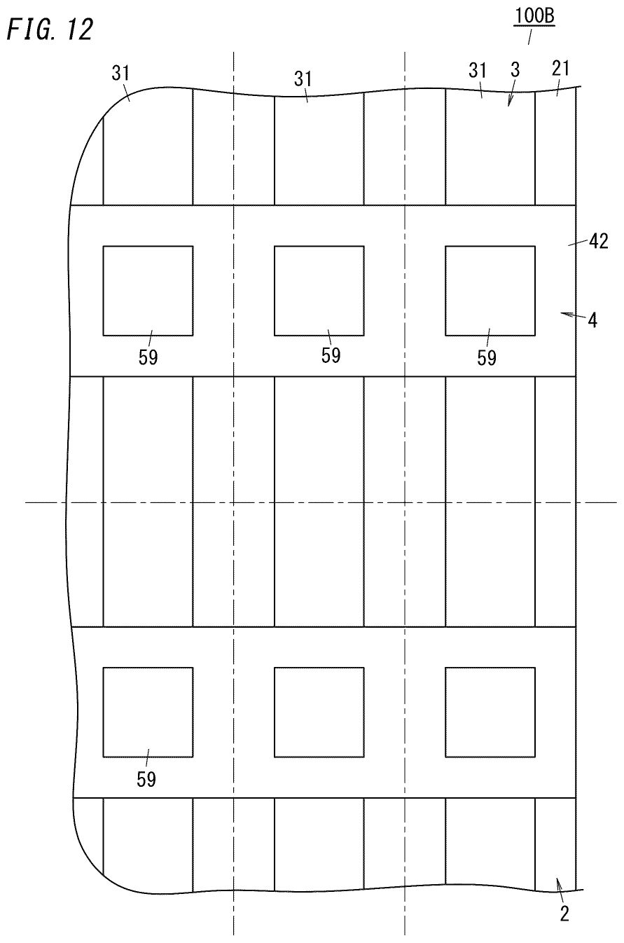

The patterning process step includes patterning the β-Ga₂O₃ layer 4 by, for example, photolithographic and etching techniques, thereby exposing each of the plurality of metallic parts 31 partially and the first principal surface 21 of the Ga₂O₃-based substrate 2 partially (refer to FIG. 12).

According to this method for fabricating the β-Ga₂O₃-based device 10B, a wafer 100B (refer to FIGS. 11 and 12) including a plurality of β-Ga₂O₃-based devices 10B may be obtained by performing the respective process steps from the substrate providing process step through the patterning process step.

According to the method for fabricating the β-Ga₂O₃-based device 10B, a plurality of β-Ga₂O₃-based devices 10B may be obtained by cutting off, in the dicing process step, the wafer 100B including a plurality of β-Ga₂O₃-based devices 10B using a dicing saw or a laser dicing device, for example. Note that the one-dot chains shown in FIG. 12 indicate dicing lines.

### (3) Advantages

A β-Ga₂O₃-based device 10B according to the second embodiment includes a Ga₂O₃-based substrate 2a, a metal layer 3a, a β-Ga₂O₃ layer 4a, and a semiconductor element 5B. The Ga₂O₃-based substrate 2a has a first principal surface 21a and a second principal surface 22a opposite from the first principal surface 21a. The metal layer 3a is formed selectively on the first principal surface 21a of the Ga₂O₃-based substrate 2a. The β-Ga₂O₃ layer 4a covers the first principal surface 21a of the Ga₂O₃-based substrate 2a and the metal layer 3a. The semiconductor element 5B includes at least a part of the β-Ga₂O₃ layer 4a. The metal layer 3a is made of a material such as a noble metal or a refractory metal. The thickness T12 of the β-Ga₂O₃ layer 4a is smaller than the thickness T11 of the Ga₂O₃-based substrate 2a.

The β-Ga₂O₃-based device 10B according to the second embodiment has such a configuration, and therefore, shortens the distance between the first metal electrode layer 58 and the second metal electrode layer 59, and cuts down the loss, compared to a situation where the first metal electrode layer 58 is provided on the second principal surface 22a, not on the first principal surface 21a, of the Ga₂O₃-based substrate 2a, thus contributing to improving the characteristics.

In the β-Ga₂O₃-based device 10B according to the second embodiment, the semiconductor element 5B is a Schottky barrier diode. In the semiconductor element 5B, the entire second metal electrode layer 59 overlaps with a part of the first metal electrode layer 58 when viewed in plan in the thickness direction D20 defined with respect to the Ga₂O₃-based substrate 2a, the second metal electrode layer 59 serves as an anode electrode, and the n⁺-type β-Ga₂O₃ layer 41a and the first metal electrode layer 58 serve as a cathode electrode. This allows the β-Ga₂O₃-based device 10B according to the second embodiment to contribute to improving the characteristics of a Schottky barrier diode.

In the β-Ga₂O₃-based device 10B according to the second embodiment, the semiconductor element 5B may improve the characteristics of the Schottky barrier diode as long as at least a part of the second metal electrode layer 59 overlaps with at least a part of the first metal electrode layer 58 when viewed in plan in the thickness direction D20 defined with respect to the Ga₂O₃-based substrate 2a.

### Third Embodiment

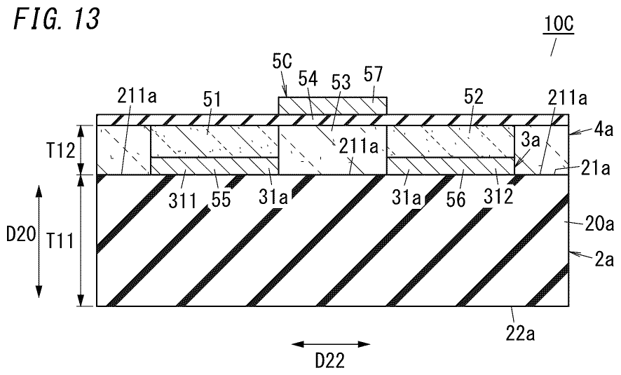

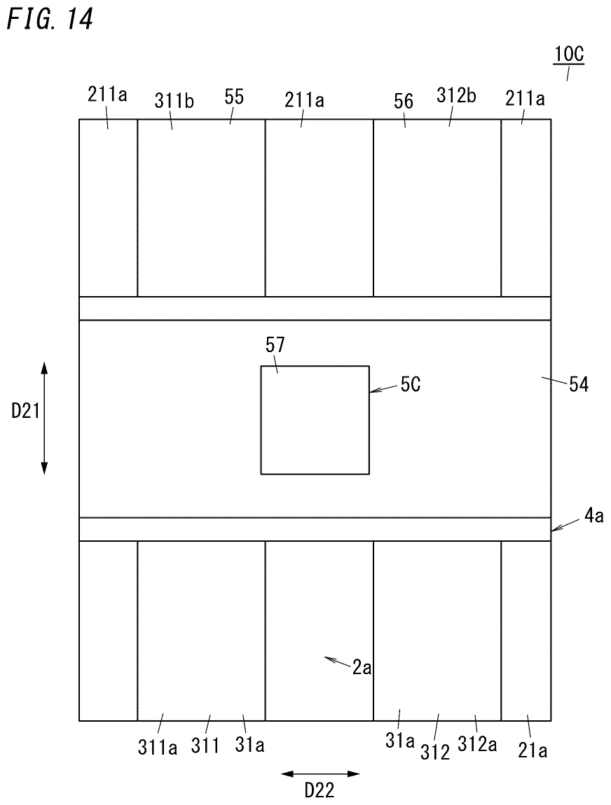

Next, a β-Ga₂O₃-based device 10C according to a third embodiment and a method for fabricating the β-Ga₂O₃-based device 10C will be described with reference to FIGS. 13 and 14. In the following description, any constituent element of the β-Ga₂O₃-based device 10C according to this third embodiment, having the same function as a counterpart of the β-Ga₂O₃-based device 10 (refer to FIGS. 6 and 7) according to the first embodiment described above, will be designated by the same reference numeral as that counterpart's, and description thereof will be omitted as appropriate herein.

### (1) β-Ga₂O₃-Based Device

The β-Ga₂O₃-based device 10C according to the third embodiment will be described with reference to FIGS. 13 and 14.

The β-Ga₂O₃-based device 10C according to the third embodiment includes a Ga₂O₃-based substrate 2a, a metal layer 3a, a β-Ga₂O₃ layer 4a, and a semiconductor element 5C.

The Ga₂O₃-based substrate 2a has a first principal surface 21a and a second principal surface 22a opposite from the first principal surface 21a.

The Ga₂O₃-based substrate 2a is a β-Ga₂O₃ substrate 20a. Also, the β-Ga₂O₃ substrate 20a is a semi-insulating β-Ga₂O₃ substrate. The Ga₂O₃-based substrate 2a has a rectangular shape when viewed in plan in the thickness direction D20 defined with respect to the Ga₂O₃-based substrate 2a.

The metal layer 3a may be made of a material such as a noble metal or a refractory metal. If a noble metal is used as a material for the metal layer 3a, the noble metal may be Pt or Au, for example, but may also be any noble metal other than Pt and Au. If a refractory metal is used as a material for the metal layer 3a, the refractory metal may be Ta or W, for example, but may also be any refractory metal other than Ta and W.

The metal layer 3a is formed selectively on the first principal surface 21a of the Ga₂O₃-based substrate 2a.

The β-Ga₂O₃ layer 4a covers the first principal surface 21a of the Ga₂O₃-based substrate 2a partially and the metal layer 3a partially. More specifically, the β-Ga₂O₃ layer 4a covers not only each of three parts 211a, not covered with the metal layer 3a, of the first principal surface 21a of the Ga₂O₃-based substrate 2a partially but also the metal layer 3a partially.

The semiconductor element 5C includes at least a part of the β-Ga₂O₃ layer 4a. The semiconductor element 5C will be described later.

In the β-Ga₂O₃-based device 10C, the metal layer 3a includes two metallic parts 31a. Each of the two metallic parts 31a has a linear shape. In the following description, the longitudinal axis of the two metallic parts 31a is herein defined to be a first direction D21 (refer to FIG. 14) and a direction perpendicular to both the thickness direction D20 defined with respect to the Ga₂O₃-based substrate 2a and the first direction D21 is herein defined to be a second direction D22.

The semiconductor element 5C is a MOSFET, and includes a drain region 51, a source region 52, a channel forming region 53, a gate insulating film 54, a drain electrode 55, a source electrode 56, and a gate electrode 57 as shown in FIG. 13. The drain region 51, the source region 52, and the channel forming region 53 are defined in the β-Ga₂O₃ layer 4a.

In the β-Ga₂O₃-based device 10C, the Ga₂O₃-based substrate 2a is a semi-insulating β-Ga₂O₃ substrate.

The β-Ga₂O₃ layer 4a is an n-type β-Ga₂O₃ layer. The n-type β-Ga₂O₃ layer contains an n-type impurity (such as Sn, Si, or Ge). The β-Ga₂O₃ layer 4a is an epitaxial layer which has been grown epitaxially on the Ga₂O₃-based substrate 2a as a base member. In the following description, the β-Ga₂O₃ layer 4a will be hereinafter sometimes referred to as an “n-type β-Ga₂O₃ layer 4a.”

The plurality of metallic parts 31a includes a first metallic part 311 and a second metallic part 312 which are adjacent to each other in the direction (second direction D22) in which the plurality of metallic parts 31a are arranged side by side. As shown in FIG. 14, the first metallic part 311 has a first end 311a and a second end 311b in the first direction D21, and the second metallic part 312 has a first end 312a and a second end 312b in the first direction D21.

As shown in FIG. 13, the drain region 51 is configured as an n⁺-type β-Ga₂O₃ region defined in the n-type β-Ga₂O₃ layer 4a to be located on the first metallic part 311. The carrier concentration in the n⁺-type β-Ga₂O₃ region serving as the drain region 51 is higher than the carrier concentration in the n-type β-Ga₂O₃ layer 4a. The drain region 51 overlaps with the first metallic part 311 in the thickness direction D20 defined with respect to the Ga₂O₃-based substrate 2a. The drain region 51 is in contact with the first metallic part 311. In this embodiment, the drain region 51 is electrically connected to the first metallic part 311. In other words, the first metallic part 311 makes an ohmic contact with the drain region 51. In the β-Ga₂O₃-based device 10C, the first metallic part 311 serves as the drain electrode 55.

The source region 52 is configured as an n⁺-type β-Ga₂O₃ region defined in the n-type β-Ga₂O₃ layer 4a to be located on the second metallic part 312. The carrier concentration in the n⁺-type β-Ga₂O₃ region serving as the source region 52 is higher than the carrier concentration in the n-type β-Ga₂O₃ layer 4a. The source region 52 overlaps with the second metallic part 312 in the thickness direction D20 defined with respect to the Ga₂O₃-based substrate 2a. The source region 52 is in contact with the second metallic part 312. In this embodiment, the source region 52 is electrically connected to the source electrode 56. In other words, the second metallic part 312 makes an ohmic contact with the source region 52. In the β-Ga₂O₃-based device 10C, the second metallic part 312 serves as the source electrode 56.

The channel forming region 53 is defined between the drain region 51 and the source region 52 in the n-type β-Ga₂O₃ layer 4a.

The gate insulating film 54 is formed over the n-type β-Ga₂O₃ layer 4a, the drain region 51, and the source region 52. Examples of materials for the gate insulating film 54 include silicon oxide, hafnium oxide, aluminum nitride, silicon nitride, and aluminum oxide.

The gate electrode 57 is formed on the gate insulating film 54. The gate electrode 57 is located between the drain region 51 and the source region 52 when viewed in plan in the thickness direction D20 defined with respect to the Ga₂O₃-based substrate 2a. A material for the gate electrode 57 may be Au or Pt, for example, but may also be a metal other than Au and Pt or an alloy.

The β-Ga₂O₃ layer 4a is formed in such a shape that exposes the first metallic part 311 partially and the second metallic part 312 partially. In the β-Ga₂O₃-based device 10C, the β-Ga₂O₃ layer 4a is formed in such a shape that exposes a first end 311a and second end 311b of the first metallic part 311 and a first end 312a and second end 312b of the second metallic part 312. The β-Ga₂O₃ layer 4a has a rectangular shape when viewed in plan in the thickness direction D20 defined with respect to the Ga₂O₃-based substrate 2a. When measured in the second direction D22, the length of the β-Ga₂O₃ layer 4a is equal to the length of the Ga₂O₃-based substrate 2a. When measured in the first direction D21, the length of the β-Ga₂O₃ layer 4a is less than the length of the Ga₂O₃-based substrate 2a.

In the semiconductor element 5C, the first end 311a and second end 311b of the first metallic part 311 serving as the drain electrode 55 may be used as electrode pads of the drain electrode 55. Also, in the semiconductor element 5C, the first end 312a and second end 312b of the second metallic part 312 serving as the source electrode 56 may be used as electrode pads of the source electrode 56.

### (2) Method for Fabricating β-Ga₂O₃-Based Device

Next, an exemplary method for fabricating the β-Ga₂O₃-based device 10C will be described briefly with reference to FIGS. 4A, 4B, 4E, 13, and 14. As for the same process steps as those of the method for fabricating the β-Ga₂O₃-based device 10 according to the first embodiment, the description thereof will be omitted as appropriate herein.

The method for fabricating the β-Ga₂O₃-based device 10C includes a substrate providing process step, a metal layer forming process step, an epitaxial growing process step, a drain/source region forming process step, an insulating film forming process step, an electrode forming process step, a patterning process step, and a dicing process step.

The substrate providing process step includes providing a Ga₂O₃-based substrate 2 having a first principal surface 21 and a second principal surface 22 opposite from the first principal surface 21 (refer to FIG. 4A). The Ga₂O₃-based substrate 2 is a wafer configured as a β-Ga₂O₃ substrate 20 and is a wafer as a prototype of the Ga₂O₃-based substrate 2a.

The metal layer forming process step includes forming a metal layer 3 having a plurality of metallic parts 31 and a plurality of openings 32 on the first principal surface 21 of the Ga₂O₃-based substrate 2 (refer to FIG. 4B). Each of the plurality of metallic parts 31 will be the metallic part 31a. The width of each of the plurality of metallic parts 31 is equal to the width of a corresponding one of the plurality of metallic parts 31a as measured in the second direction D22 (refer to FIGS. 13 and 14). On the other hand, the length of each of the plurality of metallic parts 31 is greater than the length of a corresponding one of the plurality of metallic parts 31a as measured in the first direction D21 (refer to FIG. 14).

The epitaxial growing process step includes forming a β-Ga₂O₃ layer 4 by epitaxial lateral overgrowth using a mist CVD method to cover the first principal surface 21 of the Ga₂O₃-based substrate 2 and the metal layer 3 (refer to FIG. 4E). In this embodiment, the β-Ga₂O₃ layer 4 is an n-type β-Ga₂O₃ layer, which is a prototype of the β-Ga₂O₃ layer 4a. The β-Ga₂O₃ layer 4 is a prototype of the n-type β-Ga₂O₃ layer 4a. An epitaxial wafer 1 is fabricated by performing the substrate providing process step, the metal layer forming process step, and the epitaxial growing process step. Alternatively, in the epitaxial growing process step, an MBE method or an HVPE method, for example, may be adopted instead of the mist CVD method.

The drain/source region forming process step includes forming a plurality of drain regions 51 (refer to FIG. 13) and a plurality of source regions 52 (refer to FIG. 13) in the β-Ga₂O₃ layer 4 by, for example, ion implantation and diffusion techniques.

The insulating film forming process step includes forming a gate insulating film 54 by CVD method, for example.

The electrode forming process step includes forming a plurality of gate electrodes 57 by evaporation process, for example.

The patterning process step includes patterning the β-Ga₂O₃ layer 4 by, for example, photolithographic and etching techniques, thereby exposing each of the plurality of metallic parts 31 partially and the first principal surface 21 of the Ga₂O₃-based substrate 2 partially.

According to this method for fabricating the β-Ga₂O₃-based device 10C, a wafer including a plurality of β-Ga₂O₃-based devices 10C may be obtained by performing the respective process steps from the substrate providing process step through the patterning process step.

According to the method for fabricating the β-Ga₂O₃-based device 10C, a plurality of β-Ga₂O₃-based devices 10C may be obtained by cutting off, in the dicing process step, the wafer including a plurality of β-Ga₂O₃-based devices 10C using a dicing saw or a laser dicing device, for example.

### (3) Advantages

A β-Ga₂O₃-based device 10C according to the third embodiment includes a Ga₂O₃-based substrate 2a, a metal layer 3a, a β-Ga₂O₃ layer 4a, and a semiconductor element 5C. The Ga₂O₃-based substrate 2a has a first principal surface 21a and a second principal surface 22a opposite from the first principal surface 21a. The metal layer 3a is formed selectively on the first principal surface 21a of the Ga₂O₃-based substrate 2a. The β-Ga₂O₃ layer 4a covers the first principal surface 21a of the Ga₂O₃-based substrate 2a and the metal layer 3a. The semiconductor element 5C includes at least a part of the β-Ga₂O₃ layer 4a. The metal layer 3a is made of a material such as a noble metal or a refractory metal. The thickness T12 of the β-Ga₂O₃ layer 4a is smaller than the thickness T11 of the Ga₂O₃-based substrate 2a.

The β-Ga₂O₃-based device 10C according to the third embodiment, having such a configuration, allows for contributing to improving the characteristics.

In the β-Ga₂O₃-based device 10C according to the third embodiment, the semiconductor element 5C is a MOSFET. The drain region 51, source region 52, and channel forming region 53 of the MOSFET are defined in the β-Ga₂O₃ layer 4a. This allows the β-Ga₂O₃-based device 10C according to the third embodiment to contribute to improving the characteristics of a MOSFET serving as the semiconductor element 5C.

### Fourth Embodiment

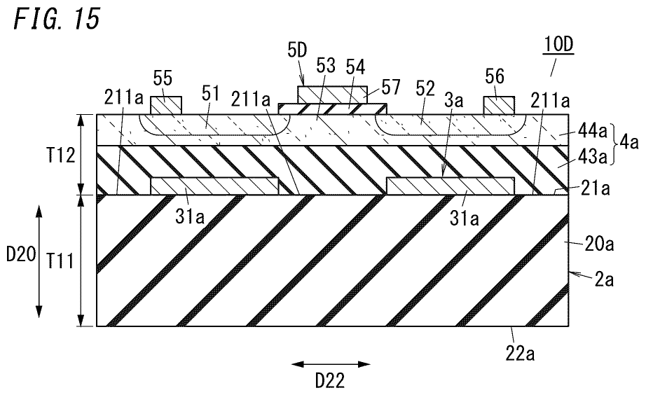

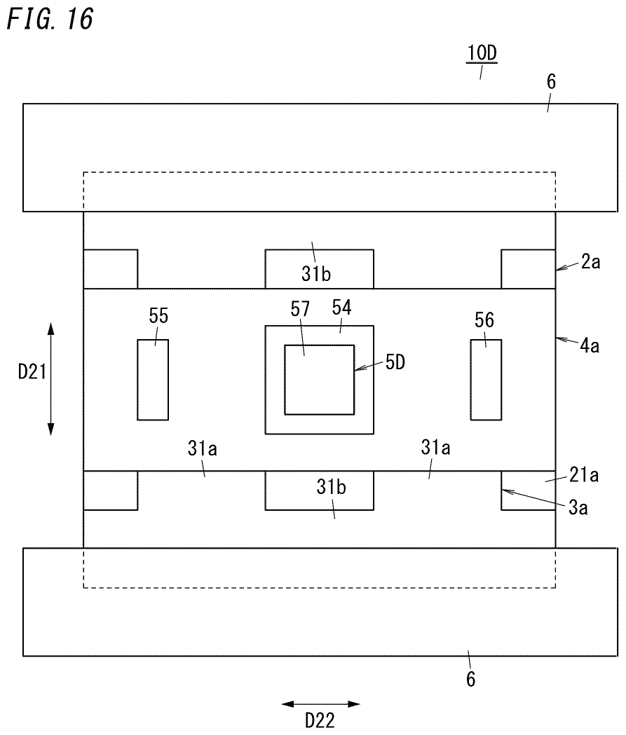

Next, a β-Ga₂O₃-based device 10D according to a fourth embodiment and a method for fabricating the β-Ga₂O₃-based device 10D will be described with reference to FIGS. 15 and 16. In the following description, any constituent element of the β-Ga₂O₃-based device 10D according to this fourth embodiment, having the same function as a counterpart of the β-Ga₂O₃-based device 10 (refer to FIGS. 6 and 7) according to the first embodiment described above, will be designated by the same reference numeral as that counterpart's, and description thereof will be omitted as appropriate herein.

### (1) β-Ga₂O₃-Based Device

The β-Ga₂O₃-based device 10D according to the fourth embodiment will be described with reference to FIGS. 15 and 16.

The β-Ga₂O₃-based device 10D according to the fourth embodiment includes a Ga₂O₃-based substrate 2a, a metal layer 3a, a β-Ga₂O₃ layer 4a, and a semiconductor element 5D.

The Ga₂O₃-based substrate 2a has a first principal surface 21a and a second principal surface 22a opposite from the first principal surface 21a.

The Ga₂O₃-based substrate 2a is a β-Ga₂O₃ substrate 20a. Also, the β-Ga₂O₃ substrate 20a is a semi-insulating β-Ga₂O₃ substrate. The Ga₂O₃-based substrate 2a has a rectangular shape when viewed in plan in the thickness direction D20 defined with respect to the Ga₂O₃-based substrate 2a.

The metal layer 3a may be made of a material such as a noble metal or a refractory metal. If a noble metal is used as a material for the metal layer 3a, the noble metal may be Pt or Au, for example, but may also be any noble metal other than Pt and Au. If a refractory metal is used as a material for the metal layer 3a, the refractory metal may be Ta or W, for example, but may also be any refractory metal other than Ta and W.

The metal layer 3a is formed selectively on the first principal surface 21a of the Ga₂O₃-based substrate 2a.

The β-Ga₂O₃ layer 4a covers the first principal surface 21a of the Ga₂O₃-based substrate 2a partially and the metal layer 3a partially. More specifically, the β-Ga₂O₃ layer 4a covers not only each of three parts 211a, not covered with the metal layer 3a, of the first principal surface 21a of the Ga₂O₃-based substrate 2a partially but also the metal layer 3a partially.

The semiconductor element 5D includes at least a part of the β-Ga₂O₃ layer 4a. The semiconductor element 5D will be described later.

In the β-Ga₂O₃-based device 10D, the metal layer 3a includes two metallic parts 31a and two more metallic parts 31b (refer to FIG. 16). Each of the two metallic parts 31a and the two more metallic parts 31b has a linear (elongate) shape. One end of each of the two metallic parts 31a is connected to one of the two metallic parts 31b, while the other end of each of the two metallic parts 31a is connected to the other of the two metallic parts 31b. In the following description, the longitudinal axis of the two metallic parts 31a is herein defined to be a first direction D21 (refer to FIG. 16) and a direction perpendicular to both the thickness direction D20 defined with respect to the Ga₂O₃-based substrate 2a and the first direction D21 is herein defined to be a second direction D22.

The semiconductor element 5D is a MOSFET, and includes a drain region 51, a source region 52, a channel forming region 53, a gate insulating film 54, a drain electrode 55, a source electrode 56, and a gate electrode 57 as shown in FIG. 15. The drain region 51, the source region 52, and the channel forming region 53 are defined in the β-Ga₂O₃ layer 4a.

In the β-Ga₂O₃-based device 10D, the Ga₂O₃-based substrate 2a is a semi-insulating β-Ga₂O₃ substrate.

In the β-Ga₂O₃-based device 10D, the β-Ga₂O₃ layer 4a includes: a semi-insulating β-Ga₂O₃ layer 43a in contact with the first principal surface 21a of the Ga₂O₃-based substrate 2a and the metal layer 3a; and an n-type β-Ga₂O₃ layer 44a formed on the semi-insulating β-Ga₂O₃ layer 43a.

The drain region 51 is configured as an n⁺-type β-Ga₂O₃ region defined in the n-type β-Ga₂O₃ layer 44a. Each of the n-type β-Ga₂O₃ layer 44a and the n⁺-type β-Ga₂O₃ region serving as the drain region 51 contains an n-type impurity (such as Sn, Si, or Ge). The drain region 51 overlaps with one of the two metallic parts 31a in the thickness direction D20 defined with respect to the Ga₂O₃-based substrate 2a.

The source region 52 is configured as an n⁺-type β-Ga₂O₃ region defined in the n-type β-Ga₂O₃ layer 44a. Each of the n-type β-Ga₂O₃ layer 44a and the n⁺-type β-Ga₂O₃ region serving as the source region 52 contains an n-type impurity (such as Sn, Si, or Ge). The source region 52 overlaps with the other of the two metallic parts 31a in the thickness direction D20 defined with respect to the Ga₂O₃-based substrate 2a.

The channel forming region 53 is defined between the drain region 51 and the source region 52 in the n-type β-Ga₂O₃ layer 4a.

The gate insulating film 54 is formed over the n-type β-Ga₂O₃ layer 4a, the drain region 51, and the source region 52. Examples of materials for the gate insulating film 54 include silicon oxide, hafnium oxide, aluminum nitride, silicon nitride, and aluminum oxide.

The gate electrode 57 is formed on the gate insulating film 54. The gate electrode 57 is located between the drain region 51 and the source region 52 when viewed in plan in the thickness direction D20 defined with respect to the Ga₂O₃-based substrate 2a. A material for the gate electrode 57 may be Au or Pt, for example, but may also be a metal other than Au and Pt or an alloy.

The drain electrode 55 is formed on the drain region 51. The drain electrode 55 is electrically connected to the drain region 51.

The source electrode 56 is formed on the source region 52. The source electrode 56 is electrically connected to the source region 52.

The metal layer 3a has exposed parts which are not covered with the β-Ga₂O₃ layer 4a. In the β-Ga₂O₃-based device 10D, the β-Ga₂O₃ layer 4a is formed in such a shape that exposes the two metallic parts 31b. The β-Ga₂O₃ layer 4a has a rectangular shape when viewed in plan in the thickness direction D20 defined with respect to the Ga₂O₃-based substrate 2a. When measured in the second direction D22, the length of the β-Ga₂O₃ layer 4a is equal to the length of the Ga₂O₃-based substrate 2a. When measured in the first direction D21, the length of the β-Ga₂O₃ layer 4a is less than the length of the Ga₂O₃-based substrate 2a and less than the length of each metallic part 31a.

The β-Ga₂O₃-based device 10D further includes two heat sinks 6. The two heat sinks 6 are arranged on the exposed parts of the metal layer 3a. More specifically, the two heat sinks 6 correspond one to one to the two metallic parts 31b of the metal layer 3a. Each of the two heat sinks 6 is disposed on a corresponding one of the two metallic parts 31b. Each of the two heat sinks 6 has a plate shape. Each of the two heat sinks 6 has the shape of a rectangle, of which the longitudinal axis is defined by the second direction D22, when viewed in plan in the thickness direction D20 defined with respect to the Ga₂O₃-based substrate 2a. Examples of materials for the two heat sinks 6 include aluminum, copper, an aluminum alloy, and a copper alloy.

### (2) Method for Fabricating β-Ga₂O₃-Based Device

Next, an exemplary method for fabricating the β-Ga₂O₃-based device 10D will be described briefly with reference to FIGS. 4A, 15, and 16. As for the same process steps as those of the method for fabricating the β-Ga₂O₃-based device 10 according to the first embodiment, description thereof will be omitted as appropriate herein.

The method for fabricating the β-Ga₂O₃-based device 10D includes a substrate providing process step, a metal layer forming process step, an epitaxial growing process step, a drain/source region forming process step, an insulating film forming process step, an electrode forming process step, a patterning process step, a dicing process step, and a bonding process step.

The substrate providing process step includes providing a Ga₂O₃-based substrate 2 having a first principal surface 21 and a second principal surface 22 opposite from the first principal surface 21 (refer to FIG. 4A). The Ga₂O₃-based substrate 2 is a wafer configured as a β-Ga₂O₃ substrate 20 and is a wafer as a prototype of the Ga₂O₃-based substrate 2a.

The metal layer forming process step includes forming, on the first principal surface 21 of the Ga₂O₃-based substrate 2, a metal layer 3 as a prototype of the metal layer 3a.

The epitaxial growing process step includes forming a semi-insulating β-Ga₂O₃ layer by epitaxial lateral overgrowth using a mist CVD method to cover the first principal surface 21 of the Ga₂O₃-based substrate 2 and the metal layer 3 and forming an n-type β-Ga₂O₃ layer by a mist CVD method to cover the semi-insulating β-Ga₂O₃ layer. The semi-insulating β-Ga₂O₃ layer is a prototype of the semi-insulating β-Ga₂O₃ layer 43a. The n-type β-Ga₂O₃ layer is a prototype of the n-type β-Ga₂O₃ layer 44a. Alternatively, in the epitaxial growing process step, an MBE method or an HVPE method, for example, may be adopted instead of the mist CVD method.

The drain/source region forming process step includes forming a plurality of drain regions 51 (refer to FIG. 15) and a plurality of source regions 52 (refer to FIG. 15) in the n-type β-Ga₂O₃ layer by, for example, ion implantation and diffusion techniques.

The insulating film forming process step includes forming a plurality of gate insulating films 54 by CVD method, for example.

The electrode forming process step includes forming a plurality of drain electrodes 55, a plurality of source electrodes 56, and a plurality of gate electrodes 57 by evaporation process, for example.

The patterning process step includes patterning the β-Ga₂O₃ layer by, for example, photolithographic and etching techniques, thereby exposing the metal layer 3 partially and the first principal surface 21 of the Ga₂O₃-based substrate 2 partially.

According to this method for fabricating the β-Ga₂O₃-based device 10D, the dicing process step is performed after the patterning process step, and then the two heat sinks 6 are bonded to the exposed parts of the metal layer 3a.

### (3) Advantages

A β-Ga₂O₃-based device 10D according to the fourth embodiment includes a Ga₂O₃-based substrate 2a, a metal layer 3a, a β-Ga₂O₃ layer 4a, and a semiconductor element 5D. The Ga₂O₃-based substrate 2a has a first principal surface 21a and a second principal surface 22a opposite from the first principal surface 21a. The metal layer 3a is formed selectively on the first principal surface 21a of the Ga₂O₃-based substrate 2a. The β-Ga₂O₃ layer 4a covers the first principal surface 21a of the Ga₂O₃-based substrate 2a and the metal layer 3a. The semiconductor element 5D includes at least a part of the β-Ga₂O₃ layer 4a. The metal layer 3a is made of a material such as a noble metal or a refractory metal. The thickness T12 of the β-Ga₂O₃ layer 4a is smaller than the thickness T11 of the Ga₂O₃-based substrate 2a.

The β-Ga₂O₃-based device 10D according to the fourth embodiment, having such a configuration, allows for contributing to improving the characteristics.

In the β-Ga₂O₃-based device 10D according to the fourth embodiment, the semiconductor element 5D is a MOSFET. The drain region 51, source region 52, and channel forming region 53 of the MOSFET are defined in the β-Ga₂O₃ layer 4a. The β-Ga₂O₃-based device 10D according to the fourth embodiment includes the heat sinks 6 arranged on exposed parts of the metal layer 3a, thus allowing for improving the heat dissipation properties and thereby contributing to improving the characteristics of a MOSFET serving as the semiconductor element 5D.

### Fifth Embodiment

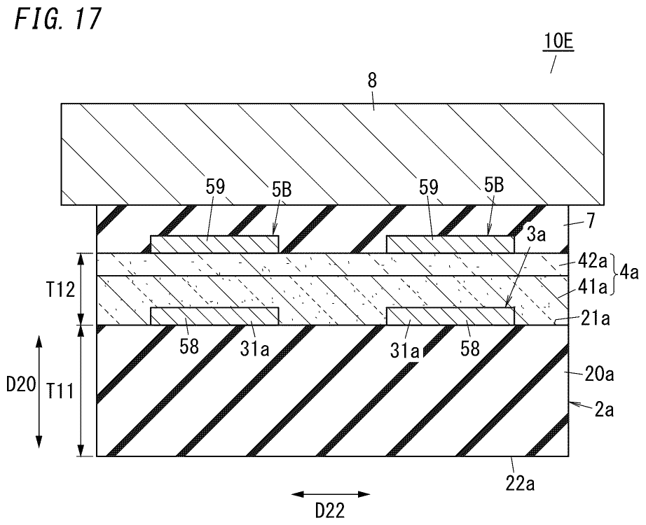

Next, a β-Ga₂O₃-based device 10E according to a fifth embodiment will be described with reference to FIG. 17. In the following description, any constituent element of the β-Ga₂O₃-based device 10E according to this fifth embodiment, having the same function as a counterpart of the β-Ga₂O₃-based device 10B (refer to FIGS. 9 and 10) according to the second embodiment described above, will be designated by the same reference numeral as that counterpart's, and description thereof will be omitted as appropriate herein.

The β-Ga₂O₃-based device 10E according to the fifth embodiment includes two semiconductor elements 5B and further includes a heat dissipating layer 7 and a heat sink 8, which is a difference from the β-Ga₂O₃-based device 10B according to the second embodiment.

The heat dissipating layer 7 is formed on the semiconductor elements 5B and has electrical insulation properties. The heat dissipating layer 7 partially covers the second metal electrode layer 59 of each of the two semiconductor elements 5B and also covers the β-Ga₂O₃ layer 4a. The heat dissipating layer 7 contains an AlN filler. Note that the heat dissipating layer 7 is formed by, for example, applying a material including the AlN filler by spin coating or any other technique and then curing the material thus applied.

The heat sink 8 is disposed on the heat dissipating layer 7. The heat sink 8 has a plate shape. The heat sink 8 has the shape of a rectangle, of which the longitudinal axis is defined by the second direction D22, when viewed in plan in the thickness direction D20 defined with respect to the Ga₂O₃-based substrate 2a. Examples of materials for the heat sink 8 include aluminum, copper, an aluminum alloy, and a copper alloy.

The β-Ga₂O₃-based device 10E according to the fifth embodiment includes the heat dissipating layer 7 and the heat sink 8, thus allowing for improving the heat dissipation properties.

### Sixth Embodiment

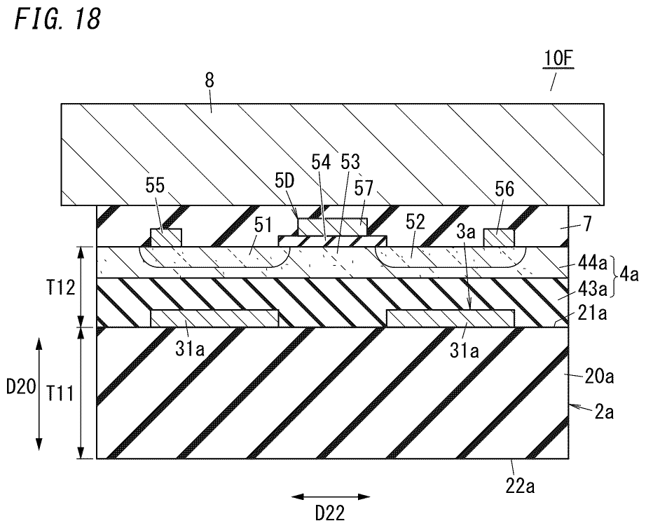

Next, a β-Ga₂O₃-based device 10F according to a sixth embodiment will be described with reference to FIG. 18. In the following description, any constituent element of the β-Ga₂O₃-based device 10F according to this sixth embodiment, having the same function as a counterpart of the β-Ga₂O₃-based device 10D (refer to FIGS. 15 and 16) according to the fourth embodiment described above, will be designated by the same reference numeral as that counterpart's, and description thereof will be omitted as appropriate herein.

The β-Ga₂O₃-based device 10F according to the sixth embodiment further includes a heat dissipating layer 7 and a heat sink 8, which is a difference from the β-Ga₂O₃-based device 10D according to the fourth embodiment.

The heat dissipating layer 7 is formed on the semiconductor element 5D and has electrical insulation properties. The heat dissipating layer 7 partially covers the drain electrode 55, the source electrode 56, and the gate electrode 57 of the semiconductor elements 5D. The heat dissipating layer 7 contains an AlN filler. Note that the heat dissipating layer 7 is formed by, for example, applying a material including the AlN filler by spin coating or any other technique and then curing the material thus applied.

The heat sink 8 is disposed on the heat dissipating layer 7. The heat sink 8 has a plate shape. The heat sink 8 has the shape of a rectangle, of which the longitudinal axis is defined by the second direction D22, when viewed in plan in the thickness direction D20 defined with respect to the Ga₂O₃-based substrate 2a. Examples of materials for the heat sink 8 include aluminum, copper, an aluminum alloy, and a copper alloy.

The β-Ga₂O₃-based device 10F according to the sixth embodiment includes the heat dissipating layer 7 and the heat sink 8, thus allowing for improving the heat dissipation properties.

### Seventh Embodiment

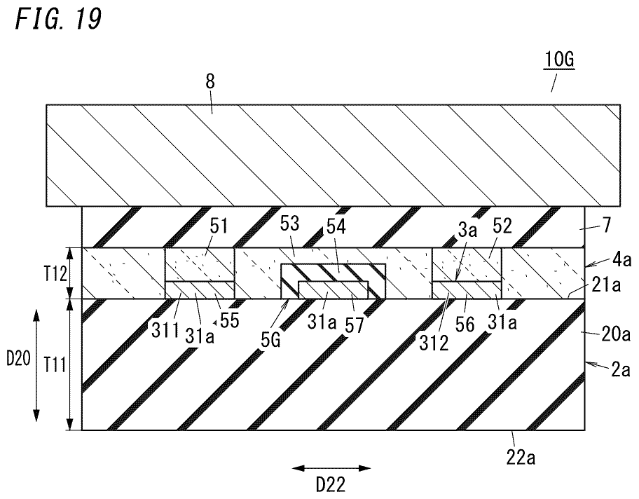

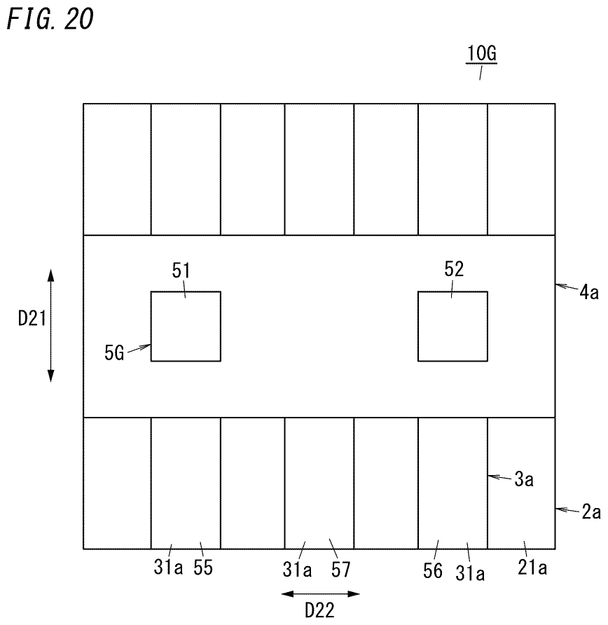

Next, a β-Ga₂O₃-based device 10G according to a seventh embodiment will be described with reference to FIGS. 19 and 20. In the following description, any constituent element of the β-Ga₂O₃-based device 10G according to this seventh embodiment, having the same function as a counterpart of the β-Ga₂O₃-based device 10C (refer to FIGS. 13 and 14) according to the third embodiment described above, will be designated by the same reference numeral as that counterpart's, and description thereof will be omitted as appropriate herein.

The β-Ga₂O₃-based device 10G according to the seventh embodiment includes a semiconductor element 5G instead of the semiconductor element 5C according to the third embodiment, which is a difference from the β-Ga₂O₃-based device 10C according to the third embodiment described above.

In the β-Ga₂O₃-based device 10G according to the seventh embodiment, the metal layer 3a includes three metallic parts 31a which are arranged side by side in the second direction D22 and the central one (31a) of the three metallic parts 31a in the second direction D22 serves as the gate electrode 57, which is a difference from the β-Ga₂O₃-based device 10C according to the third embodiment described above.

In addition, the β-Ga₂O₃-based device 10G according to the seventh embodiment further includes a gate insulating film 54 that covers the gate electrode 57. Examples of materials for the gate insulating film 54 include silicon oxide, hafnium oxide, aluminum nitride, silicon nitride, and aluminum oxide.

In the β-Ga₂O₃-based device 10G according to the seventh embodiment, the β-Ga₂O₃ layer 4a covers the gate insulating film 54 as well.

The β-Ga₂O₃-based device 10G according to the seventh embodiment further includes a heat dissipating layer 7 and a heat sink 8, which is a difference from the β-Ga₂O₃-based device 10C according to the third embodiment described above. Note that illustration of the heat dissipating layer 7 and the heat sink 8 is omitted in FIG. 20.

The heat dissipating layer 7 is formed on the semiconductor element 5G and has electrical insulation properties. The heat dissipating layer 7 covers the drain region 51, the source region 52, and the channel forming region 53 of the semiconductor element 5G and the β-Ga₂O₃ layer 4a. The heat dissipating layer 7 contains an AlN filler. Note that the heat dissipating layer 7 is formed by, for example, applying a material including the AlN filler by spin coating or any other technique and then curing the material thus applied.

The heat sink 8 is disposed on the heat dissipating layer 7. The heat sink 8 has a plate shape. The heat sink 8 has the shape of a rectangle, of which the longitudinal axis is defined by the second direction D22, when viewed in plan in the thickness direction D20 defined with respect to the β-Ga₂O₃-based substrate 2a. Examples of materials for the heat sink 8 include aluminum, copper, an aluminum alloy, and a copper alloy.

The β-Ga₂O₃-based device 10G according to the seventh embodiment includes the heat dissipating layer 7 and the heat sink 8, thus allowing for improving the heat dissipation properties.

### Eighth Embodiment

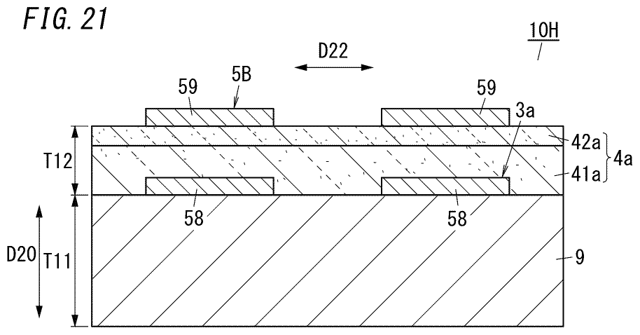

Next, a β-Ga₂O₃-based device 10H according to an eighth embodiment and a method for fabricating the β-Ga₂O₃-based device 10H will be described with reference to FIGS. 21, 22, 23A, 23B, and 23C. In the following description, any constituent element of the β-Ga₂O₃-based device 10H according to this eighth embodiment, having the same function as a counterpart of the β-Ga₂O₃-based device 10B (refer to FIGS. 9 and 10) according to the second embodiment described above, will be designated by the same reference numeral as that counterpart's, and description thereof will be omitted as appropriate herein.

### (1) β-Ga₂O₃-Based Device

The β-Ga₂O₃-based device 10H according to the eighth embodiment will be described with reference to FIG. 21.

The β-Ga₂O₃-based device 10H according to the eighth embodiment includes a heat sink 9 instead of the Ga₂O₃-based substrate 2a of the β-Ga₂O₃-based device 10B according to the second embodiment, which is a difference from the β-Ga₂O₃-based device 10B according to the second embodiment described above.

In addition, in the β-Ga₂O₃-based device 10H according to the eighth embodiment, the shape of the metal layer 3a is different from that of the metal layer 3a of the β-Ga₂O₃-based device 10B according to the second embodiment.

The heat sink 9 has a plate shape. The heat sink 9 has the shape of a rectangle, of which the longitudinal axis is defined by the second direction D22, when viewed in plan in the thickness direction D20 defined with respect to the Ga₂O₃-based substrate 2a. Examples of materials for the heat sink 9 include aluminum, copper, an aluminum alloy, and a copper alloy.

### (2) Method for Fabricating β-Ga₂O₃-Based Device

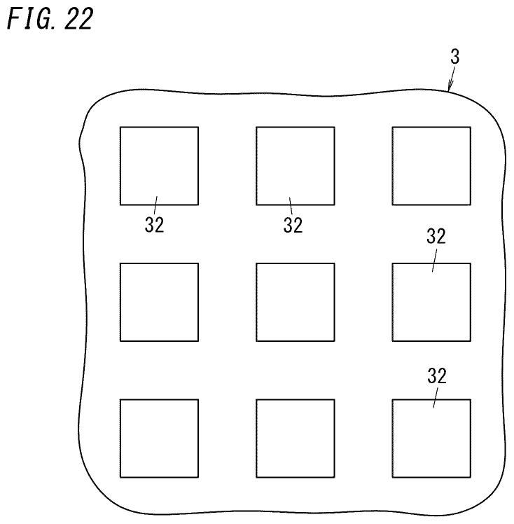

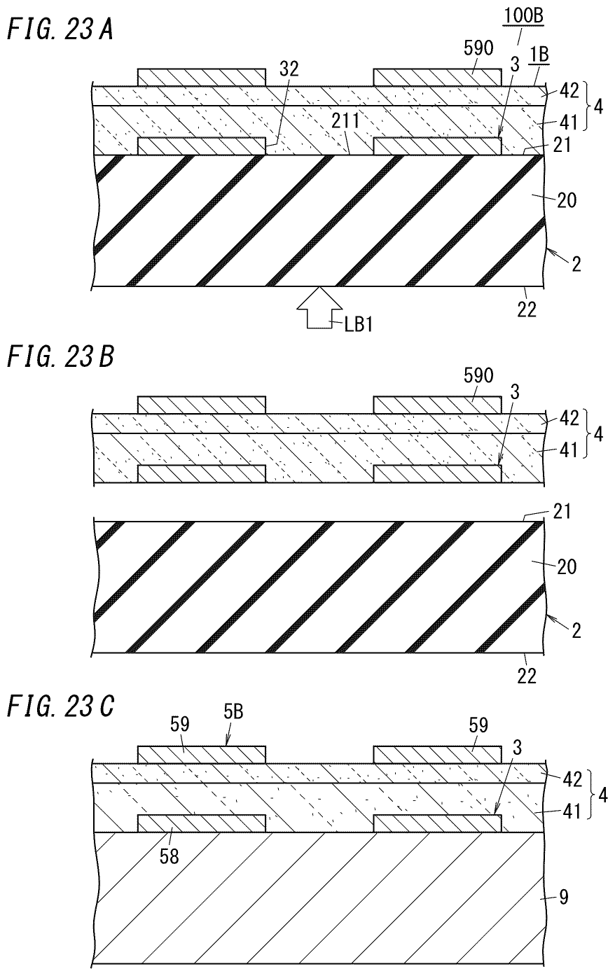

Next, a method for fabricating the β-Ga₂O₃-based device 10H according to the eighth embodiment will be described with reference to FIGS. 22, 23B, and 23C.

The method for fabricating the β-Ga₂O₃-based device 10H according to the eighth embodiment, as well as the method for fabricating the β-Ga₂O₃-based device 10B according to the second embodiment, also includes a substrate providing process step, a metal layer forming process step, an epitaxial growing process step, an electrode layer forming process step, a patterning process step, and a dicing process step.

The method for fabricating the β-Ga₂O₃-based device 10H according to the eighth embodiment further includes a laser liftoff process step and a bonding process step, which is a difference from the method for fabricating the β-Ga₂O₃-based device 10B according to the second embodiment. The laser liftoff process step and the bonding process step are performed, for example, between the patterning process step and the dicing process step.

The substrate providing process step, the metal layer forming process step, the epitaxial growing process step, the electrode layer forming process step, and the patterning process step are substantially the same as those of the second embodiment described above, and description thereof will be omitted herein. The metal layer forming process step includes forming a metal layer 3, having a plurality of openings 32 which are arranged to form a two-dimensional array as shown in FIG. 22, on the Ga₂O₃-based substrate 2 (refer to FIG. 4A). The metal layer 3 is a prototype of the metal layer 3a. Each of the plurality of openings 32 has a square shape. The metal layer 3 has a grid shape.

The epitaxial growing process step includes forming an n⁺-type β-Ga₂O₃ layer 41 (refer to FIG. 11) by epitaxial lateral overgrowth using a mist CVD method to cover the first principal surface 21 of the Ga₂O₃-based substrate 2 and the metal layer 3 and forming an n-type β-Ga₂O₃ layer 42 (refer to FIG. 11) by a mist CVD method to cover the n⁺-type β-Ga₂O₃ layer 41. The n⁺-type β-Ga₂O₃ layer 41 is a prototype of the n⁺-type β-Ga₂O₃ layer 41a. The n-type β-Ga₂O₃ layer 42 is a prototype of the n-type β-Ga₂O₃ layer 42a. An epitaxial wafer 1B (refer to FIG. 11) is fabricated by performing the substrate providing process step, the metal layer forming process step, and the epitaxial growing process step. Alternatively, in the epitaxial growing process step, an MBE method or an HVPE method, for example, may be adopted instead of the mist CVD method. In this embodiment, the n⁺-type β-Ga₂O₃ layer 41 and the n-type β-Ga₂O₃ layer 42 form the β-Ga₂O₃ layer 4.

The electrode layer forming process step includes forming a metal electrode layer 590 (refer to FIG. 23A) by evaporation, for example. Note that the electrode layer forming process step includes forming the metal electrode layer 590 on the β-Ga₂O₃ layer 4. The metal electrode layer 590 is a prototype of the second metal electrode layer 59.

The patterning process step includes patterning the β-Ga₂O₃ layer 4 by, for example, photolithographic and etching techniques, thereby exposing a part of the metal layer 3 and a part of the first principal surface 21 of the Ga₂O₃-based substrate 2.

The laser liftoff process step includes stripping the Ga₂O₃-based substrate 2 from the metal layer 3 and the β-Ga₂O₃ layer 4 (refer to FIG. 23B) by irradiating the Ga₂O₃-based substrate 2 with a laser beam LB1 (refer to FIG. 23A) from the second principal surface 22 thereof.

The bonding process step includes bonding the heat sink 9 onto the exposed surface of the metal layer 3 and the exposed surface of the β-Ga₂O₃ layer 4 (refer to FIG. 23C).

In the method for fabricating the β-Ga₂O₃-based device 10H according to the eighth embodiment, the dicing process step is performed after the bonding process step, thereby obtaining a plurality of β-Ga₂O₃-based devices 10H.

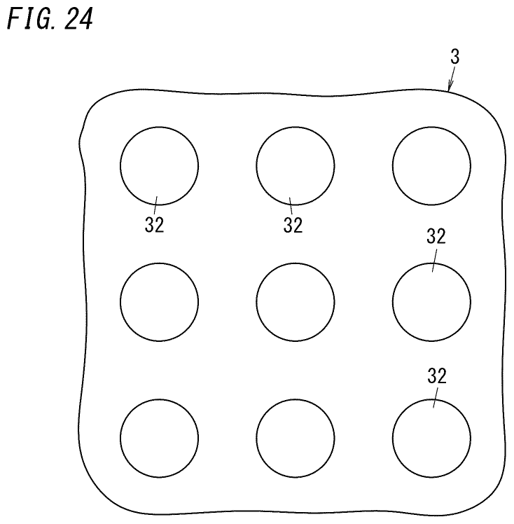

The method for fabricating the β-Ga₂O₃-based device 10H according to the eighth embodiment allows for improving the heat dissipation properties of the β-Ga₂O₃-based device 10H. 224 In the metal layer 3 formed by the method for fabricating the β-Ga₂O₃-based device 10H according to the eighth embodiment, each of the plurality of openings 32 arranged to form a two-dimensional array may have a circular shape as shown in FIG. 24.

### Variations

Note that the first to eighth embodiments and their variations described above are only exemplary ones of various embodiments of the present disclosure and their variations and should not be construed as limiting. Rather, the first to eighth embodiments and their variations may be readily modified in various manners depending on a design choice or any other factor without departing from the scope of the present disclosure.

For example, in the epitaxial wafers 1, 1A, the plurality of openings 32 of the metal layer 3 may be arranged to form a two-dimensional array as shown in FIG. 22 or 24. This makes it easier to further reduce the thickness of the Ga₂O₃-based substrate 2, 2A while the Ga₂O₃-based substrate 2, 2A is being polished from the second principal surface 22, 22A of the Ga₂O₃-based substrate 2, 2A.

Also, in the β-Ga₂O₃-based devices 10, 10D, 10E, 10F, the metal layer 3 may have a plurality of openings 32 arranged to form a two-dimensional array as shown in FIG. 22 or 24. This makes it easier to further reduce the thickness of the Ga₂O₃-based substrate 2a, thus allowing the heat dissipation properties to be further improved.

Furthermore, the Ga₂O₃-based substrate 2 does not have to be the β-Ga₂O₃ substrate 20 but may also be a β-(Gaₓ, Al₁₋ₓ)₂O₃ substrate (where 0<x<1), for example. Furthermore, the Ga₂O₃-based substrate 2 does not have to be the β-Ga₂O₃ substrate 20 but may also be an α-Ga₂O₃ substrate or an α-(Gaₓ, Al₁₋ₓ)₂O₃ substrate (where 0<x<1), for example. Optionally, the Ga₂O₃-based substrate 2 may contain Fe or Al as an impurity.

Furthermore, in the β-Ga₂O₃-based device 10, the semiconductor element 5 is a MESFET. Alternatively, the semiconductor element 5 may also have a configuration including, instead of the β-Ga₂O₃ layer 4a, a β-Ga₂O₃ layer and a β-(Gaₓ, Al₁₋ₓ)₂O₃ layer (where 0<x<1) formed on the β-Ga₂O₃ layer. In that case, a high electron mobility transistor (HEMT) may be formed as the semiconductor element 5 instead of the MESFET.

The transistor serving as the semiconductor element included in the β-Ga₂O₃-based device does not have to be the MESFET or the MOSFET but may also be a HEMT.

Furthermore, the FET serving as the semiconductor element included in the β-Ga₂O₃-based device does not have to be a transverse FET in which a drain electrode and a source electrode are formed on the β-Ga₂O₃ layer but may also be a longitudinal FET in which a drain electrode and a source electrode are arranged to be stacked one on top of the other in the thickness direction defined with respect to the β-Ga₂O₃ layer.

Optionally, according to the method for fabricating the β-Ga₂O₃-based device 10H, the Ga₂O₃-based substrate 2A may be used instead of the Ga₂O₃-based substrate 2.

### Aspects

The foregoing description provides specific implementations for the following aspects of the present disclosure.

An epitaxial wafer (1; 1A) according to a first aspect includes a Ga₂O₃-based substrate (2; 2A), a metal layer (3), and a β-Ga₂O₃ layer (4). The Ga₂O₃-based substrate (2; 2A) has a first principal surface (21; 21A) and a second principal surface (22; 22A) opposite from the first principal surface (21; 21A). The metal layer (3) is formed on the first principal surface (21; 21A) of the Ga₂O₃-based substrate (2; 2A). The metal layer (3) has a plurality of openings (32). The β-Ga₂O₃ layer (4) covers the first principal surface (21; 21A) of the Ga₂O₃-based substrate (2; 2A) and the metal layer (3). The metal layer (3) is made of a material such as a noble metal or a refractory metal. The thickness (T2) of the β-Ga₂O₃ layer (4) is smaller than the thickness (T1) of the Ga₂O₃-based substrate (2; 2A).

This aspect may contribute to improving the characteristics of a β-Ga₂O₃-based device.

In an epitaxial wafer (1; 1A) according to a second aspect, which may be implemented in conjunction with the first aspect, the metal layer (3) includes a plurality of metallic parts (31). Each of the plurality of metallic parts (31) is linear. In the metal layer (3), the plurality of metallic parts (31) and the plurality of openings (32) are arranged alternately when viewed in plan in a thickness direction (D10) defined with respect to the Ga₂O₃-based substrate (2; 2A).

This aspect makes it easier to make the Ga₂O₃-based substrate (2; 2A) even thinner when the Ga₂O₃-based substrate (2; 2A) is polished from the second principal surface (22; 22A) of the Ga₂O₃-based substrate (2; 2A).

In an epitaxial wafer (1; 1A) according to a third aspect, which may be implemented in conjunction with the first aspect, in the metal layer (3), the plurality of openings (32) are arranged to form a two-dimensional array.

This aspect makes it easier to make the Ga₂O₃-based substrate (2; 2A) even thinner when the Ga₂O₃-based substrate (2; 2A) is polished from the second principal surface (22; 22A) of the Ga₂O₃-based substrate (2; 2A).

In an epitaxial wafer (1) according to a fourth aspect, which may be implemented in conjunction with any one of the first to third aspects, the Ga₂O₃-based substrate (2) is a β-Ga₂O₃ substrate (2; 2A).

This aspect makes it easier to provide the Ga₂O₃-based substrate (2).

In an epitaxial wafer (1A) according to a fifth aspect, which may be implemented in conjunction with any one of the first to third aspects, the Ga₂O₃-based substrate (2A) includes: a sapphire substrate (24); and a β-Ga₂O₃ layer (25) formed on the sapphire substrate (24). In the Ga₂O₃-based substrate (2A), a surface (251) of the β-Ga₂O₃ layer (25) forms the first principal surface (21A) of the Ga₂O₃-based substrate (2A).

This aspect may contribute to cutting down the cost.

A β-Ga₂O₃-based device (10; 10B; 10C; 10D; 10E; 10F; 10G) according to a sixth aspect includes a Ga₂O₃-based substrate (2a), a metal layer (3a), a β-Ga₂O₃ layer (4a), and a semiconductor element (5; 5B; 5C; 5D; 5G). The Ga₂O₃-based substrate (2a) has a first principal surface (21a) and a second principal surface (22a) opposite from the first principal surface (21a). The metal layer (3a) is formed selectively on the first principal surface (21a) of the Ga₂O₃-based substrate (2a). The β-Ga₂O₃ layer (4a) covers the first principal surface (21a) of the Ga₂O₃-based substrate (2a) and the metal layer (3a). The semiconductor element (5; 5B; 5C; 5D; 5G) includes at least a part of the β-Ga₂O₃ layer (4a). The metal layer (3a) is made of a material such as a noble metal or a refractory metal. The thickness (T12) of the β-Ga₂O₃ layer (4a) is smaller than the thickness (T11) of the Ga₂O₃-based substrate (2a).

This aspect may contribute to improving the characteristics of the β-Ga₂O₃-based device (10; 10B; 10C; 10D; 10E; 10F; 10G).

In a β-Ga₂O₃-based device (10; 10C; 10D; 10E; 10F; 10G) according to a seventh aspect, which may be implemented in conjunction with the sixth aspect, the metal layer (3a) includes a plurality of metallic parts (31a). Each of the plurality of metallic parts (31a) is linear. In the metal layer (3a), the plurality of metallic parts (31a) are arranged to be spaced from each other in a direction perpendicular to each of the plurality of metallic parts (31a) when viewed in plan in a thickness direction (D20) defined with respect to the Ga₂O₃-based substrate (2a).

This aspect allows for improving the heat dissipation properties.

In a β-Ga₂O₃-based device (10) according to an eighth aspect, which may be implemented in conjunction with the seventh aspect, the semiconductor element (5) is a MESFET including a drain region (51), a source region (52), a channel forming region (53), a drain electrode (55), a source electrode (56), and a gate electrode (57). The drain region (51), the source region (52), and the channel forming region (53) are defined in the β-Ga₂O₃ layer (4a). The channel forming region (53) overlaps with one metallic part (31a) out of the plurality of metallic parts (31a) when viewed in plan in the thickness direction (D20) defined with respect to the Ga₂O₃-based substrate (2a).

This aspect may contribute to improving the characteristics of a MESFET serving as the semiconductor element (5).

In a β-Ga₂O₃-based device (10) according to a ninth aspect, which may be implemented in conjunction with the eighth aspect, the Ga₂O₃-based substrate (2a) is a semi-insulating β-Ga₂O₃ substrate. The β-Ga₂O₃ layer (4a) is an n-type β-Ga₂O₃ layer. The drain region (51) is configured as an n⁺-type β-Ga₂O₃ region defined within the n-type β-Ga₂O₃ layer (4a). The drain region (51) has a comb shape. The source region (52) is configured as an n⁺-type β-Ga₂O₃ region defined within the n-type β-Ga₂O₃ layer (4a). The source region (52) has a comb shape. The drain electrode (55) is formed on the drain region (51). The drain electrode (55) has a shape of a comb overlapping with the drain region (51) when viewed in plan in the thickness direction (D20) defined with respect to the Ga₂O₃-based substrate (2a). The source electrode (56) is formed on the source region (52). The source electrode (56) has a shape of a comb overlapping with the source region (52) when viewed in plan in the thickness direction (D20) defined with respect to the Ga₂O₃-based substrate (2a). The gate electrode (57) is formed on the n-type β-Ga₂O₃ layer (4a). The gate electrode (57) has a shape of a comb when viewed in plan in the thickness direction (D20) defined with respect to the Ga₂O₃-based substrate (2a). The drain electrode (55) includes: a drain electrode comb backbone (551); and a plurality of drain electrode comb teeth (552) extending from the drain electrode comb backbone (551). The source electrode (56) includes: a source electrode comb backbone (561); and a plurality of source electrode comb teeth (562) extending from the source electrode comb backbone (561). The gate electrode (57) includes: a gate electrode comb backbone (571); and a plurality of gate electrode comb teeth (572) extending from the gate electrode comb backbone (571). The drain electrode comb backbone (551) and the source electrode comb backbone (561) face each other in a first direction (D21). The plurality of drain electrode comb teeth (552), the plurality of gate electrode comb teeth (572), and the plurality of source electrode comb teeth (562) are arranged side by side in a second direction (D22) perpendicular to both the thickness direction (D20) defined with respect to the Ga₂O₃-based substrate (2a) and the first direction (D21). Each of the plurality of gate electrode comb teeth (572) overlaps with any one metallic part (31a) out of the plurality of metallic parts (31a) when viewed in plan in the thickness direction (D20) defined with respect to the Ga₂O₃-based substrate (2a).

This aspect may not only improve the stability of operation of a MEFET serving as the semiconductor element (5) but also increase the breakdown voltage thereof as well.

In a β-Ga₂O₃-based device (10) according to a tenth aspect, which may be implemented in conjunction with the ninth aspect, each of the plurality of gate electrode comb teeth (572) is arranged to be offset in the second direction (D22) to avoid overlapping with a center of the one metallic part (31a) in the second direction (D22) when viewed in plan in the thickness direction (D20) defined with respect to the Ga₂O₃-based substrate (2a).

This aspect may further improve the characteristics of the semiconductor element (5).

In a β-Ga₂O₃-based device (10; 10D; 10E; 10F) according to an eleventh aspect, which may be implemented in conjunction with the sixth aspect, the metal layer (3) has a plurality of openings (32) which are arranged to form a two-dimensional array.

This aspect makes it easier to further reduce the thickness of the Ga₂O₃-based substrate (2a) and improve the heat dissipation properties thereof.

In a β-Ga₂O₃-based device (10B) according to a twelfth aspect, which may be implemented in conjunction with the sixth aspect, the semiconductor element (5B) is a Schottky barrier diode. The Ga₂O₃-based substrate (2a) is a semi-insulating β-Ga₂O₃ substrate. The β-Ga₂O₃ layer (4a) includes: an n⁺-type β-Ga₂O₃ layer (41a) covering the first principal surface (21a) of the Ga₂O₃-based substrate (2a) and the metal layer (3a); and an n-type β-Ga₂O₃ layer (42a) formed on the n⁺-type β-Ga₂O₃ layer (41a). The n⁺-type β-Ga₂O₃ layer (41a) makes ohmic contact with the metal layer (3a). The semiconductor element (5B) includes: a first metal electrode layer (58) formed out of the metal layer (3a); the n⁺-type β-Ga₂O₃ layer (41a); the n-type β-Ga₂O₃ layer (42a); and a second metal electrode layer (59). The second metal electrode layer (59) is formed on, and makes Schottky contact with, the n-type β-Ga₂O₃ layer (42a). In the semiconductor element (5B), at least a part of the second metal electrode layer (59) and at least a part of the first metal electrode layer (58) overlap with each other when viewed in plan in a thickness direction (D20) defined with respect to the Ga₂O₃-based substrate (2a). In the semiconductor element (5B), the second metal electrode layer (59) serves as an anode electrode and the n⁺-type β-Ga₂O₃ layer (41) and the first metal electrode layer (58) serve as a cathode electrode.

This aspect may improve the characteristics of a Schottky barrier diode serving as the semiconductor element (5B).

In a β-Ga₂O₃-based device (10C; 10D; 10F; 10G) according to a thirteenth aspect, which may be implemented in conjunction with the seventh aspect, the semiconductor element (5C; 5D; 5G) is a MOSFET including a drain region (51), a source region (52), a channel forming region (53), a gate insulating film (54), a drain electrode (55), a source electrode (56), and a gate electrode (57). The drain region (51), the source region (52), and the channel forming region (53) are defined in the β-Ga₂O₃ layer (4a).

This aspect may contribute to improving the characteristics of a MOSFET serving as the semiconductor element (5C; 5D; 5G).

In a β-Ga₂O₃-based device (10C) according to a fourteenth aspect, which may be implemented in conjunction with the thirteenth aspect, the Ga₂O₃-based substrate (2a) is a semi-insulating β-Ga₂O₃ substrate. The β-Ga₂O₃ layer (4a) is an n-type β-Ga₂O₃ layer. The plurality of metallic parts (31a) includes a first metallic part (311) and a second metallic part (312) which are adjacent to each other in a direction in which the plurality of metallic parts (31a) are arranged side by side. The drain region (51) is configured as an n⁺-type β-Ga₂O₃ region defined on the first metallic part (311) in the β-Ga₂O₃ layer (4a). The source region (52) is configured as an n⁺-type β-Ga₂O₃ region defined on the second metallic part (312) in the β-Ga₂O₃ layer (4a). The first metallic part (311) serves as the drain electrode (55). The second metallic part (312) serves as the source electrode (56). The gate insulating film (54) is formed on the β-Ga₂O₃ layer (4a). The gate electrode (57) is formed on the gate insulating film (54). The gate electrode (57) is located between the drain region (51) and the source region (52) when viewed in plan in the thickness direction (D20) defined with respect to the Ga₂O₃-based substrate (2a). The β-Ga₂O₃ layer (4a) is formed in such a shape as to expose a part of the first metallic part (311) and a part of the second metallic part (312).

In a β-Ga₂O₃-based device (10D) according to a fifteenth aspect, which may be implemented in conjunction with the thirteenth aspect, the β-Ga₂O₃ layer (4a) includes: a semi-insulating β-Ga₂O₃ layer (43a) in contact with the metal layer (3a); and an n-type β-Ga₂O₃ layer (44a) formed on the semi-insulating β-Ga₂O₃ layer (43a). The drain region (51) is configured as an n⁺-type β-Ga₂O₃ region defined in the n-type β-Ga₂O₃ layer (44a). The source region (52) is configured as an n⁺-type β-Ga₂O₃ region defined in the n-type β-Ga₂O₃ layer (44a). The gate insulating film (54) is formed on the n-type β-Ga₂O₃ layer (44a). The gate electrode (57) is formed on the gate insulating film (54). The gate electrode (57) is located between the drain region (51) and the source region (52) when viewed in plan in the thickness direction (D20) defined with respect to the Ga₂O₃-based substrate (2a). The drain electrode (55) is formed on the drain region (51). The source electrode (56) is formed on the source region (52).

A β-Ga₂O₃-based device (10D) according to a sixteenth aspect, which may be implemented in conjunction with the fifteenth aspect, further includes a heat sink (6). The metal layer (3a) has an exposed part not covered with the β-Ga₂O₃ layer (4a). The heat sink (6) is disposed on the exposed part of the metal layer (3a).

This aspect allows for improving the heat dissipation properties.

A β-Ga₂O₃-based device (10E; 10F; 10G) according to a seventeenth aspect, which may be implemented in conjunction with the sixth aspect, further includes a heat dissipating layer (7) and a heat sink (8). The heat dissipating layer (7) is formed on the semiconductor element (5B; 5D; 5G) and has electrical insulation properties. The heat sink (8) is disposed on the heat dissipating layer (7). The heat dissipating layer (7) contains an AlN filler.

This aspect allows for improving the heat dissipation properties.

A method for fabricating a β-Ga₂O₃-based device (10; 10B; 10C; 10D; 10E; 10F; 10G; 10H) according to an eighteenth aspect includes a substrate providing process step, a metal layer forming process step, and an epitaxial growing process step. The substrate providing process step includes providing a Ga₂O₃-based substrate (2; 2A) having a first principal surface (21) and a second principal surface (22) opposite from the first principal surface (21). The metal layer forming process step includes forming a metal layer (3) having a plurality of openings (32) on the first principal surface (21; 21A) of the Ga₂O₃-based substrate (2; 2A). The epitaxial growing process step includes forming a β-Ga₂O₃ layer (4) that covers the first principal surface (21; 21A) of the Ga₂O₃-based substrate (2; 2A) and the metal layer (3) by epitaxial lateral overgrowth using a mist CVD method. The metal layer (3) is made of a material such as a noble metal or a refractory metal. The thickness (T12) of the β-Ga₂O₃ layer (4) is smaller than the thickness (T11) of the Ga₂O₃-based substrate (2; 2A).

This aspect may contribute to improving the characteristics of the β-Ga₂O₃-based device (10; 10B; 10C; 10D; 10E; 10F; 10G; 10H).

A method for fabricating a β-Ga₂O₃-based device (10H) according to a nineteenth aspect, which may be implemented in conjunction with the eighteenth aspect, further includes a laser liftoff process step and a bonding process step. The laser liftoff process step includes stripping the Ga₂O₃-based substrate (2; 2A) from the metal layer (3) and the β-Ga₂O₃ layer (4) by irradiating the Ga₂O₃-based substrate (2; 2A) with a laser beam (LB1) through the second principal surface (22; 22A) of the Ga₂O₃-based substrate (2; 2A). The bonding process step includes bonding a heat sink (9) onto an exposed surface of the metal layer (3) and an exposed surface of the β-Ga₂O₃ layer (4).

This aspect may contribute to improving the heat dissipation properties of the β-Ga₂O₃-based device (10H).

While the foregoing has described what are considered to be the best mode and/or other examples, it is understood that various modifications may be made therein and that the subject matter disclosed herein may be implemented in various forms and examples, and that they may be applied in numerous applications, only some of which have been described herein. It is intended by the following claims to claim any and all modifications and variations that fall within the true scope of the present teachings.

1. An epitaxial wafer comprising:
a Ga₂O₃-based substrate having a first principal surface and a second principal surface opposite from the first principal surface;
a metal layer formed on the first principal surface of the Ga₂O₃-based substrate and having a plurality of openings; and
a β-Ga₂O₃ layer covering the first principal surface of the Ga₂O₃-based substrate and the metal layer,
the metal layer being made of a material such as a noble metal or a refractory metal, and
a thickness of the β-Ga₂O₃ layer being smaller than a thickness of the Ga₂O₃-based substrate.

2. The epitaxial wafer of claim 1, wherein
the metal layer includes a plurality of metallic parts,
each of the plurality of metallic parts is linear, and
in the metal layer, the plurality of metallic parts and the plurality of openings are arranged alternately when viewed in plan in a thickness direction defined with respect to the Ga₂O₃-based substrate.

3. The epitaxial wafer of claim 1, wherein
in the metal layer, the plurality of openings are arranged to form a two-dimensional array.

4. The epitaxial wafer of claim 1, wherein
the Ga₂O₃-based substrate is a β-Ga₂O₃ substrate.

5. The epitaxial wafer of claim 1, wherein
the Ga₂O₃-based substrate includes:
a sapphire substrate; and
a β-Ga₂O₃ layer formed on the sapphire substrate, and
in the Ga₂O₃-based substrate, a surface of the β-Ga₂O₃ layer forms the first principal surface of the Ga₂O₃-based substrate.

6. A β-Ga₂O₃-based device comprising:
a Ga₂O₃-based substrate having a first principal surface and a second principal surface opposite from the first principal surface;
a metal layer formed selectively on the first principal surface of the Ga₂O₃-based substrate;
a β-Ga₂O₃ layer covering the first principal surface of the Ga₂O₃-based substrate and the metal layer; and
a semiconductor element,
the semiconductor element including at least a part of the β-Ga₂O₃ layer,
the metal layer being made of a material such as a noble metal or a refractory metal, and
a thickness of the β-Ga₂O₃ layer being smaller than a thickness of the Ga₂O₃-based substrate.

7. The β-Ga₂O₃-based device of claim 6, wherein
the metal layer includes a plurality of metallic parts,
each of the plurality of metallic parts is linear, and
in the metal layer, the plurality of metallic parts are arranged to be spaced from each other in a direction perpendicular to each of the plurality of metallic parts when viewed in plan in a thickness direction defined with respect to the Ga₂O₃-based substrate.

8. The β-Ga₂O₃-based device of claim 7, wherein
the semiconductor element is a MESFET including a drain region, a source region, a channel forming region, a drain electrode, a source electrode, and a gate electrode,
the drain region, the source region, and the channel forming region are defined in the β-Ga₂O₃ layer, and
the channel forming region overlaps with one metallic part out of the plurality of metallic parts when viewed in plan in the thickness direction defined with respect to the Ga₂O₃-based substrate.

9. The β-Ga₂O₃-based device of claim 8, wherein
the Ga₂O₃-based substrate is a semi-insulating β-Ga₂O₃ substrate,
the β-Ga₂O₃ layer is an n-type β-Ga₂O₃ layer,
the drain region has a comb shape and is configured as an n⁺-type β-Ga₂O₃ region defined within the n-type β-Ga₂O₃ layer,
the source region has a comb shape and is configured as an n⁺-type β-Ga₂O₃ region defined within the n-type β-Ga₂O₃ layer,
the drain electrode is formed on the drain region and has a shape of a comb overlapping with the drain region when viewed in plan in the thickness direction defined with respect to the Ga₂O₃-based substrate,
the source electrode is formed on the source region and has a shape of a comb overlapping with the source region when viewed in plan in the thickness direction defined with respect to the Ga₂O₃-based substrate,
the gate electrode is formed on the n-type β-Ga₂O₃ layer and has a shape of a comb when viewed in plan in the thickness direction defined with respect to the Ga₂O₃-based substrate,
the drain electrode includes: a drain electrode comb backbone; and a plurality of drain electrode comb teeth extending from the drain electrode comb backbone,
the source electrode includes: a source electrode comb backbone; and a plurality of source electrode comb teeth extending from the source electrode comb backbone,
the gate electrode includes: a gate electrode comb backbone; and a plurality of gate electrode comb teeth extending from the gate electrode comb backbone,
the drain electrode comb backbone and the source electrode comb backbone face each other in a first direction,
the plurality of drain electrode comb teeth, the plurality of gate electrode comb teeth, and the plurality of source electrode comb teeth are arranged side by side in a second direction perpendicular to both the thickness direction defined with respect to the Ga₂O₃-based substrate and the first direction, and
each of the plurality of gate electrode comb teeth overlaps with any one metallic part out of the plurality of metallic parts when viewed in plan in the thickness direction defined with respect to the Ga₂O₃-based substrate.

10. The β-Ga₂O₃-based device of claim 9, wherein
each of the plurality of gate electrode comb teeth is arranged to be offset in the second direction to avoid overlapping with a center of the one metallic part in the second direction when viewed in plan in the thickness direction defined with respect to the Ga₂O₃-based substrate.

11. The β-Ga₂O₃-based device of claim 6, wherein
the metal layer has a plurality of openings which are arranged to form a two-dimensional array.

12. The β-Ga₂O₃-based device of claim 6, wherein
the semiconductor element is a Schottky barrier diode,
the Ga₂O₃-based substrate is a semi-insulating β-Ga₂O₃ substrate,
the β-Ga₂O₃ layer includes:
an n⁺-type β-Ga₂O₃ layer covering the first principal surface of the Ga₂O₃-based substrate and the metal layer and making ohmic contact with the metal layer; and
an n-type β-Ga₂O₃ layer formed on the n⁺-type β-Ga₂O₃ layer,
the semiconductor element includes:
a first metal electrode layer formed out of the metal layer;
the n⁺-type β-Ga₂O₃ layer;
the n-type β-Ga₂O₃ layer; and
a second metal electrode layer formed on, and making Schottky contact with, the n-type β-Ga₂O₃ layer, and
in the semiconductor element,
at least a part of the second metal electrode layer and at least a part of the first metal electrode layer overlap with each other when viewed in plan in a thickness direction defined with respect to the Ga₂O₃-based substrate, and
the second metal electrode layer serves as an anode electrode and the n⁺-type β-Ga₂O₃ layer and the first metal electrode layer serve as a cathode electrode.

13. The β-Ga₂O₃-based device of claim 7, wherein
the semiconductor element is a MOSFET including a drain region, a source region, a channel forming region, a gate insulating film, a drain electrode, a source electrode, and a gate electrode, and
the drain region, the source region, and the channel forming region are formed in the β-Ga₂O₃ layer.

14. The β-Ga₂O₃-based device of claim 13, wherein
the Ga₂O₃-based substrate is a semi-insulating β-Ga₂O₃ substrate,
the β-Ga₂O₃ layer is an n-type β-Ga₂O₃ layer,
the plurality of metallic parts includes a first metallic part and a second metallic part which are adjacent to each other in a direction in which the plurality of metallic parts are arranged side by side,
the drain region is configured as an n⁺-type β-Ga₂O₃ region defined on the first metallic part in the β-Ga₂O₃ layer,
the source region is configured as an n⁺-type β-Ga₂O₃ region defined on the second metallic part in the β-Ga₂O₃ layer,
the first metallic part serves as the drain electrode,
the second metallic part serves as the source electrode,
the gate insulating film is formed on the β-Ga₂O₃ layer,
the gate electrode is formed on the gate insulating film and is located between the drain region and the source region when viewed in plan in the thickness direction defined with respect to the Ga₂O₃-based substrate, and
the β-Ga₂O₃ layer is formed in such a shape as to expose a part of the first metallic part and a part of the second metallic part.

15. The β-Ga₂O₃-based device of claim 13, wherein
the β-Ga₂O₃ layer includes:
a semi-insulating β-Ga₂O₃ layer in contact with the metal layer; and
an n-type β-Ga₂O₃ layer formed on the semi-insulating β-Ga₂O₃ layer,
the drain region is configured as an n⁺-type β-Ga₂O₃ region defined in the n-type β-Ga₂O₃ layer,
the source region is configured as an n⁺-type β-Ga₂O₃ region defined in the n-type β-Ga₂O₃ layer,
the gate insulating film is formed on the n-type β-Ga₂O₃ layer,
the gate electrode is formed on the gate insulating film and located between the drain region and the source region when viewed in plan in the thickness direction defined with respect to the Ga₂O₃-based substrate,
the drain electrode is formed on the drain region, and
the source electrode is formed on the source region.

16. The β-Ga₂O₃-based device of claim 15, further comprising a heat sink, wherein
the metal layer has an exposed part not covered with the β-Ga₂O₃ layer, and
the heat sink is disposed on the exposed part of the metal layer.

17. The β-Ga₂O₃-based device of claim 6, further comprising:
a heat dissipating layer formed on the semiconductor element and having electrical insulation properties; and
a heat sink disposed on the heat dissipating layer, wherein
the heat dissipating layer contains an AlN filler.

18. A method for fabricating a β-Ga₂O₃-based device, the method comprising:
a substrate providing process step including providing a Ga₂O₃-based substrate having a first principal surface and a second principal surface opposite from the first principal surface;
a metal layer forming process step including forming a metal layer having a plurality of openings on the first principal surface of the Ga₂O₃-based substrate; and
an epitaxial growing process step including forming a β-Ga₂O₃ layer that covers the first principal surface of the Ga₂O₃-based substrate and the metal layer by epitaxial lateral overgrowth using a mist CVD method,
the metal layer being made of a material such as a noble metal or a refractory metal, and
a thickness of the β-Ga₂O₃ layer being smaller than a thickness of the Ga₂O₃-based substrate.

19. The method of claim 18, further comprising:
a laser liftoff process step including stripping the Ga₂O₃-based substrate from the metal layer and the β-Ga₂O₃ layer by irradiating the Ga₂O₃-based substrate with a laser beam through the second principal surface of the Ga₂O₃-based substrate; and
a bonding process step including bonding a heat sink onto an exposed surface of the metal layer and an exposed surface of the β-Ga₂O₃ layer.
